(19) United States
(12) Patent Application Publication
(10) Pub. No.: US 2011/0155062 A1
(43) Pub. Date: Jun. 30, 2011

(54) FILM DEPOSITION APPARATUS

(75) Inventors: Hitoshi KATO, Iwate (JP); Yasushi TAKEUCHI, Iwate (JP)

(73) Assignee: TOKYO ELECTRON LIMITED, Tokyo (JP)

(21) Appl. No.: 12/965,955

(22) Filed: Dec. 13, 2010

(30) Foreign Application Priority Data
Dec. 25, 2009 (JP) 2009-295392

(51) Int. Cl. C23C 16/00

(52) U.S. Cl. 118/728

(57) ABSTRACT

A film deposition apparatus includes a turntable including a substrate placement region at its surface; first and second reaction gas supply parts disposed in first and second supply regions in a chamber and supplying first and second reaction gases onto the surface, respectively; a separation region disposed between the first and second supply regions, the separation region including a separation gas supply part ejecting a separation gas separating the first and second reaction gases and a ceiling surface forming a separation space to supply the separation gas to the first and second supply regions; and first and second evacuation ports provided for the first and second supply regions. At least one of the first and second evacuation ports is disposed so as to guide the separation gas, supplied to the corresponding supply region, toward and along a direction in which the corresponding reaction gas supply part extends.

### CROSS-REFERENCE TO RELATED APPLICATION

The present application is based upon and claims the benefit of priority of Japanese Patent Application No. 2009-295392, filed on Dec. 25, 2009, the entire contents of which are incorporated herein by reference.

### BACKGROUND OF THE INVENTION

1. Field of the Invention

The present invention relates to a film deposition apparatus configured to deposit a thin film on a substrate by stacking multiple layers of a reaction product by carrying out multiple times the cycle of supplying, in turn, at least two kinds of reaction gases that react with each other onto the substrate in a chamber.

2. Description of the Related Art

As a film deposition technique in a semiconductor manufacturing process, a process is known where a first reaction gas is caused to be adsorbed, under vacuum, onto the surface of a semiconductor wafer (hereinafter, referred to as “wafer”) or the like, which is a substrate; the gas to supply is thereafter switched to a second reaction gas to form one or more atomic or molecular layers through reaction of the gases on the surface of the wafer; and this cycle is repeated multiple times to deposit a film on the substrate. This process is called, for example, atomic layer deposition (ALD) or molecular layer deposition (MLD) (hereinafter referred to as ALD), and is expected to be an effective technique capable of addressing reduction in the film thickness of semiconductor devices because of its capability of controlling film thickness with high accuracy in accordance with the number of cycles and its excellent in-plane uniformity of film quality.

For example, Japanese Laid-Open Patent Application No. 2001-254181 proposes, as an apparatus configured to carry out such a film deposition method, an apparatus that performs film deposition by placing four wafers at equal angular intervals on a wafer support member (or a turntable) along its rotation direction; placing a first reaction gas nozzle to eject a first reaction gas and a second reaction gas nozzle to eject a second reaction gas at equal angular intervals along the rotation direction so that the first reaction gas nozzle and the second reaction gas nozzle face the wafer support member; disposing separation gas nozzles between these reaction gas nozzles; and horizontally rotating the wafer support member. In such an ALD apparatus of a turntable type, the first reaction gas and the second reaction gas are prevented from mixing by a separation gas from the separation gas nozzles.

In the case of using a separation gas, however, the reaction gases are diluted with the separation gas, so that it may be necessary to supply the reaction gases in large amounts in order to maintain a sufficient film deposition rate.

Japanese National Publication of International Patent Application No. 2008-516428 (or United States Patent Publication No. 2006/0073276) discloses a film deposition apparatus capable of preventing a separation gas (purge gas) from diluting precursors by introducing the precursors (reaction gases) into relatively-flat gas regions defined above a turning substrate holder (turntable); controlling the flow of the precursors in these regions; and discharging the precursors upward through exhaust zones provided one on each side of each region.

### SUMMARY OF THE INVENTION

According to one aspect of the present invention, a film deposition apparatus is provided that deposits a thin film on a substrate by stacking a plurality of layers of a reaction product by carrying out a plurality of times a cycle of supplying, in turn, at least two kinds of reaction gases reacting with each other onto the substrate in a chamber. This film deposition apparatus includes a turntable provided rotatably in the chamber and including a substrate placement region for placing a substrate on a surface thereof; a first reaction gas supply part disposed in a first supply region in the chamber so as to extend in a direction to cross a rotation direction of the turntable, and configured to supply a first reaction gas onto the surface of the turntable; a second reaction gas supply part disposed in a second supply region spaced apart from the first supply region along the rotation direction of the turntable so as to extend in a direction to cross the rotation direction of the turntable, and configured to supply a second reaction gas onto the surface of the turntable; a separation region disposed between the first supply region and the second supply region, the separation region including a separation gas supply part configured to eject a separation gas to separate the first reaction gas and the second reaction gas; and a ceiling surface forming a separation space having a predetermined height between the ceiling surface and the surface of the turntable to supply the separation gas from the separation gas supply part to the first supply region and the second supply region; a first evacuation port provided for the first supply region; and a second evacuation port provided for the second supply region. At least one of the first evacuation port and the second evacuation port is disposed so as to guide the separation gas, supplied from the separation region to the first or second supply region corresponding to said at least one of the first evacuation port and the second evacuation port, toward and along a direction in which the first or second reaction gas supply part in the corresponding first or second supply region extends.

### BRIEF DESCRIPTION OF THE DRAWINGS

Other objects, features and advantages of the present invention will become more apparent from the following detailed description when read in conjunction with the accompanying drawings, in which:

FIG. 1 is a cross-sectional view of a film deposition apparatus according to an embodiment of the present invention;

FIG. 2 is a perspective view of the film deposition apparatus of FIG. 1, schematically illustrating its internal configuration, according to the embodiment of the present invention;

FIG. 3 is a plan view of the film deposition apparatus of FIG. 1 according to the embodiment of the present invention;

FIGS. 4A and 4B are cross-sectional views of the film deposition apparatus of FIG. 1, illustrating a supply region and a separation region, according to the embodiment of the present invention;

FIGS. 5A and 5B are diagrams for illustrating the size of the separation region according to the embodiment of the present invention;

FIG. 6 is another cross-sectional view of the film deposition apparatus of FIG. 1 according to the embodiment of the present invention;

FIG. 7 is yet another cross-sectional view of the film deposition apparatus of FIG. 1 according to the embodiment of the present invention;

FIG. 8 is a cutaway perspective view of part of the film deposition apparatus of FIG. 1 according to the embodiment of the present invention;

FIG. 9 is a diagram illustrating a gas flow pattern in a vacuum chamber of the film deposition apparatus of FIG. 1 according to the embodiment of the present invention;

FIG. 10 is another diagram illustrating a gas flow pattern in the vacuum chamber of the film deposition apparatus of FIG. 1 according to the embodiment of the present invention;

FIGS. 11A and 11B are plan views of the film deposition apparatus of FIG. 1, illustrating variations of the supply region, according to the embodiment of the present invention;

FIGS. 12A and 12B are diagrams illustrating a reaction gas nozzle and a nozzle cover in the film deposition apparatus of FIG. 1 according to the embodiment of the present invention;

FIG. 13 is a diagram illustrating the reaction gas nozzle to which the nozzle cover of FIGS. 12A and 12B is attached according to the embodiment of the present invention;

FIGS. 14A through 140 are diagrams illustrating a variation of the nozzle cover according to the embodiment of the present invention;

FIGS. 15A and 15B are diagrams illustrating a reaction gas injector used in the film deposition apparatus of FIG. 1 according to the embodiment of the present invention;

FIGS. 16A and 16B are diagrams illustrating another reaction gas injector used in the film deposition apparatus of FIG. 1 according to the embodiment of the present invention;

FIGS. 17A and 17B are diagrams illustrating results of a simulation with respect to a reaction gas concentration according to the embodiment of the present invention;

FIGS. 18A and 18B are diagrams illustrating results of other simulations with respect to the reaction gas concentration according to the embodiment of the present invention;

FIG. 19 is a graph illustrating the results of the simulations with respect to the reaction gas concentration according to the embodiment of the present invention;

FIGS. 20A and 20B are diagrams illustrating variations of the reaction gas nozzle according to the embodiment of the present invention;

FIG. 21 is a cross-sectional view of a film deposition apparatus according to another embodiment of the present invention; and

FIG. 22 is a schematic diagram illustrating a substrate processor including a film deposition apparatus according to an embodiment of the present invention.

### DETAILED DESCRIPTION OF THE PREFERRED EMBODIMENTS

As described above, Japanese National Publication of International Patent Application No. 2008-516428 (or United States Patent Publication No. 2006/0073276) discloses a film deposition apparatus that introduces precursors into relatively-flat gas regions. Depending on precursors, however, confining the precursors to such regions may cause their thermal decomposition to cause deposition of reaction products in the regions. The deposition of reaction products serves as a particle source, so that there may be the problem of the decrease of yield.

According to one aspect of the present invention, a film deposition apparatus is provided that is capable of reducing dilution of a first reaction gas and a second reaction gas with a separation gas used for preventing mixture of the first reaction gas and the second reaction gas.

A description is given below, with reference to the accompanying drawings, of non-limiting embodiments of the present invention illustrated as an example. In the accompanying drawings, the same or corresponding members or components are referred to by the same or corresponding reference numerals, and a redundant description thereof is omitted. Further, the drawings do not aim at showing a relative ratio between members or components, and accordingly, specific thickness and size are to be determined by those skilled in the art in light of the following non-limiting embodiments.

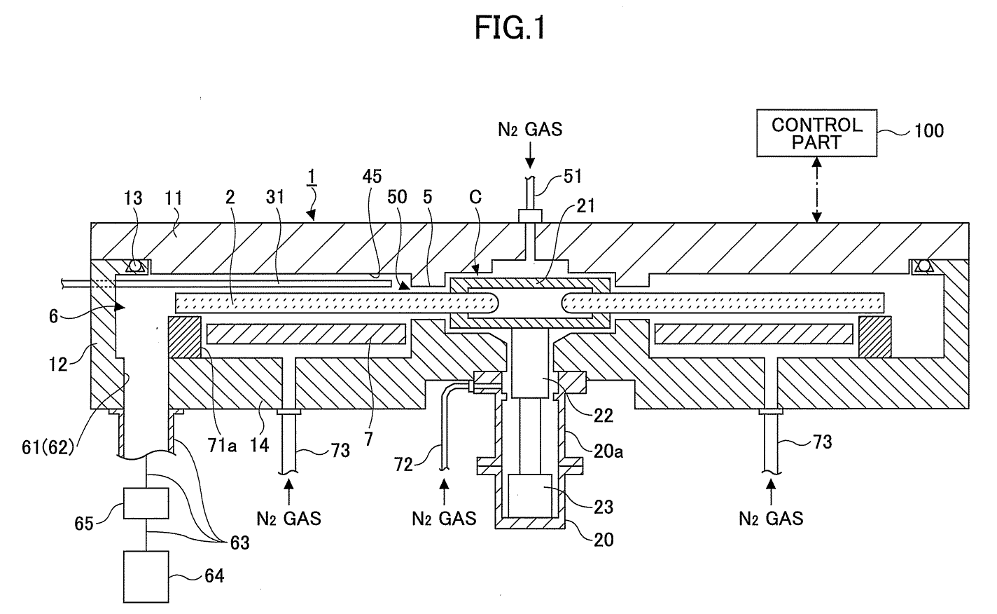

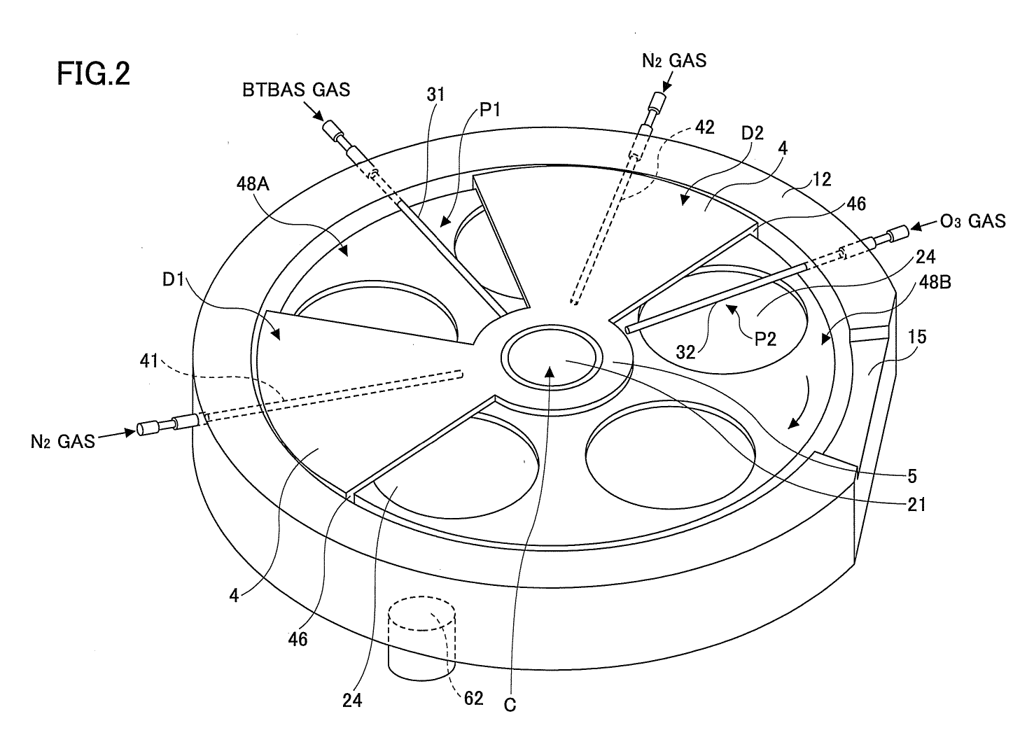

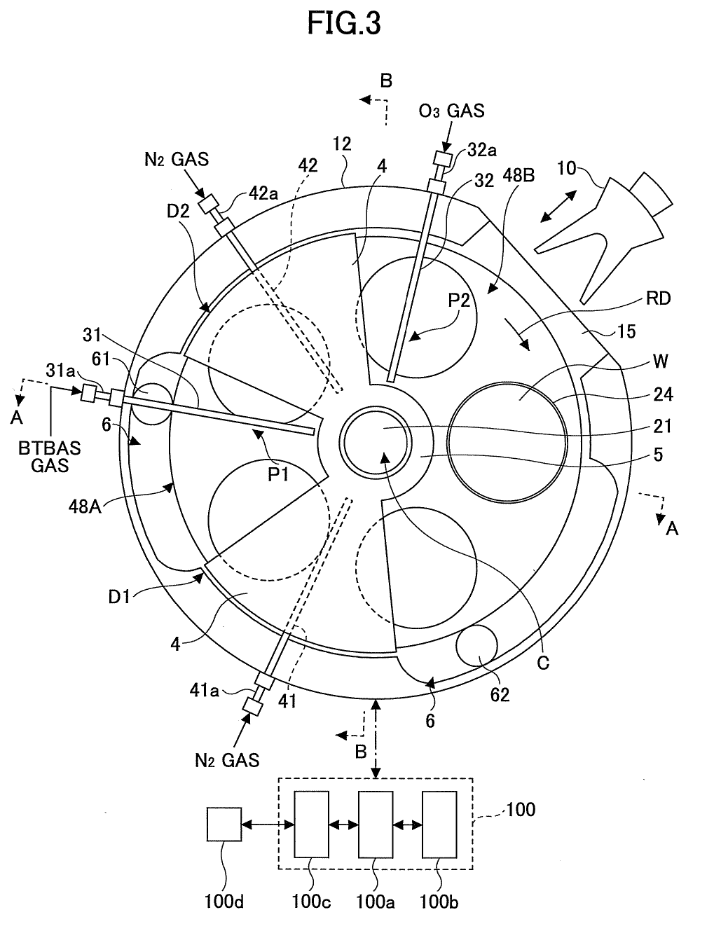

As illustrated in FIG. 1 (a cross-sectional view taken along line A-A of FIG. 3) and FIG. 2, a film deposition apparatus according to an embodiment of the present invention includes a flat vacuum chamber 1 having a substantially circular planar shape and a turntable 2 provided inside the vacuum chamber 1 to have a rotation center at the center of the vacuum chamber 1. The vacuum chamber 1 includes a chamber body 12 and a ceiling plate 11 separable from the chamber body 12. The ceiling plate 11 is attached to the chamber body 12 via a sealing member 13 such as an O ring, thereby hermetically sealing the vacuum chamber 1. The ceiling plate 11 and the chamber body 12 may be formed of, for example, aluminum (Al).

Referring to FIG. 1, the turntable 2 has a circular opening at the center, and is held from above and below by a cylindrical core part 21 around the opening. The core part 21 is fixed to the upper end of a vertically extending rotation shaft 22. The rotation shaft 22 passes through a bottom part 14 of the chamber body 12 to have its lower end attached to a drive part 23 that causes the rotation shaft 22 to rotate on a vertical axis. This configuration allows the turntable 2 to rotate with its center axis serving as a rotation center. The rotation shaft 22 and the drive part 23 are housed in a tubular case body 20 that is open at its upper end. This case body 20 is hermetically attached to the lower surface of the bottom part 14 of the chamber body 12 via a flange part 20a provided at its upper end, thereby separating the internal atmosphere of the case body 20 from the external atmosphere.

As illustrated in FIG. 2 and FIG. 3, multiple (five, in the graphically illustrated example) circularly depressed placement parts 24 for placing respective wafers W are formed at a surface (upper surface) of the turntable 2 at equal angular intervals. In FIG. 3, only one of the wafers W is illustrated.

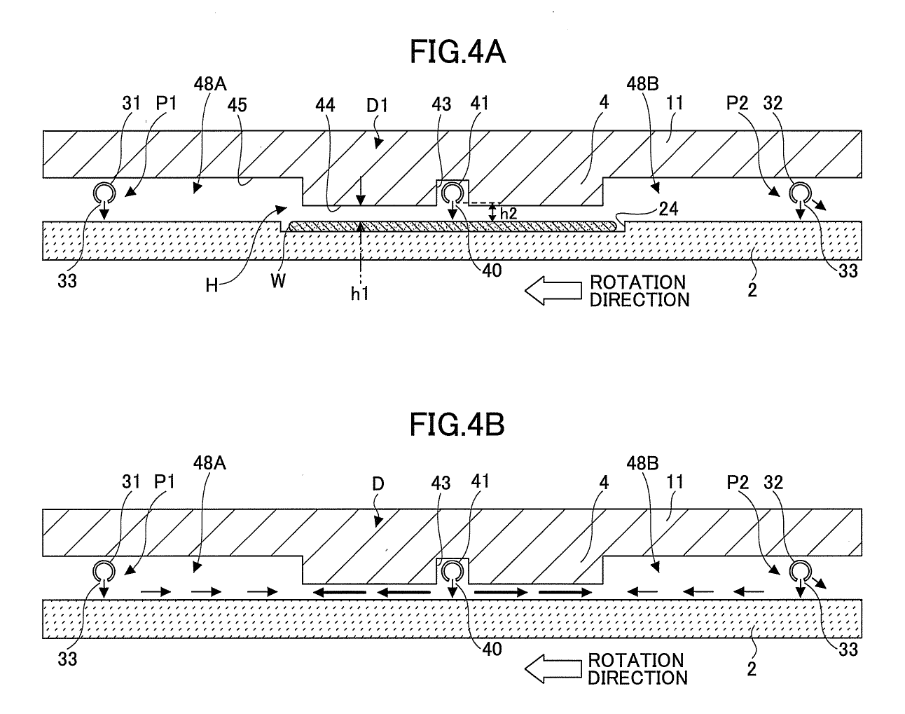

Referring to FIG. 4A, the cross sections of the placement part 24 and the wafer W placed in the placement part 24 are shown. As graphically illustrated, the placement part 24 is slightly (for example, 4 mm) larger in diameter than the wafer W, and has a depth substantially equal to the thickness of the wafer W. Since the depth of the placement part 24 is substantially equal to the thickness of the wafer W, the surface of the wafer W is substantially flush with the surface of the region of the turntable 2 except for the placement parts 24 when the wafer W is placed in the placement part 24. If there is a relatively large difference in height between the wafer W and the region, the difference in height causes turbulence in a gas flow, thereby affecting the uniformity of film thickness on the wafer W. In order to reduce this effect, the two surfaces are at substantially the same height. For “substantially the same height,” which may include cases where the difference in height is less than or equal to approximately 5 mm, the difference in height is preferably as close to zero as possible to the extent permitted by processing accuracy.

Referring to FIG. 2 through FIG. 43, two spaced-out projecting parts 4 are provided along the rotation direction of the turntable 2 (for example, indicated by arrow RD of FIG. 3). Although the ceiling plate 11 is omitted in FIG. 2 and FIG. 3, the projecting parts 4 are attached to a lower surface 45 (FIG. 4A) of the ceiling plate 11 as illustrated in FIGS. 4A and 4B. Further, as is seen from FIG. 3, the upper surface of each projecting part 4 has a substantially sectorial shape, whose vertex is positioned substantially at the center of the vacuum chamber 1 and whose arc is positioned along the inner circumferential wall surface of the chamber body 12. Further, as illustrated in FIG. 4A, the projecting parts 4 are disposed so that lower surfaces 44 thereof are positioned at height h1 from the turntable 2.

Referring to FIG. 3 and FIGS. 4A and 43, the projecting parts 4 include respective groove parts 43 that extend radially to bisect the respective projecting parts 4. The groove parts 43 house respective separation gas nozzles 41 and 42. In this embodiment, the groove parts 43 are formed so as to bisect the projecting parts 4. In other embodiments, however, the groove parts 43 may be formed so that the divided projecting parts 4 have wider portions on the upstream side in the rotation direction of the turntable 2. As illustrated in FIG. 3, the separation gas nozzles 41 and 42 are introduced into the vacuum chamber 1 through the circumferential wall part of the chamber body 12, and are supported by having respective gas introduction ports 41a and 42a, which are their base end parts, attached to the peripheral wall surface of the chamber body 12.

The separation gas nozzles 41 and 42 are connected to a gas supply source of a separation gas (not graphically illustrated). The separation gas may be nitrogen (N₂) gas or an inert gas. The separation gas is not limited to a particular kind as long as the separation gas does not affect film deposition. In this embodiment, N₂ gas is used as a separation gas. Further, the separation gas nozzles 41 and 42 have ejection holes 40 (FIGS. 4A and 4B) for ejecting N₂ gas toward the upper surface of the turntable 2. The ejection holes 40 are disposed lengthwise at predetermined intervals. In this embodiment, the ejection holes 40 have an aperture of approximately 0.5 mm, and are arranged at intervals of approximately 10 mm along the lengthwise directions of the separation gas nozzles 41 and 42.

According to the above-described configuration, a separation region D1 that defines a separation space H (FIG. 4A) is provided by the separation gas nozzle 41 and the corresponding projecting part 4. Likewise, a separation region D2 that defines a corresponding separation space H is provided by the separation gas nozzle 42 and the corresponding projecting part 4. Further, on the downstream side of the separation region D1 in the rotation direction of the turntable 2, a first region 48A (a first supply region) is formed that is substantially surrounded by the separation regions D1 and D2, the turntable 2, the lower surface 45 of the ceiling plate 11 (hereinafter, “ceiling surface 45”), and the inner circumferential wall surface of the chamber body 12. Further, on the upstream side of the separation region D1 in the rotation direction of the turntable 2, a second region 48B (a second supply region) is formed that is substantially surrounded by the separation regions D1 and D2, the turntable 2, the ceiling surface 45, and the inner circumferential wall surface of the chamber body 12. When N₂ gas is ejected from the separation gas nozzles 41 and 42 in the separation regions D1 and D2, respectively, the pressure becomes higher in the separation spaces H than in the first region 48A and the second region 48B, so that the N₂ gas flows from the separation spaces H to the first region 48A and the second region 48B. In other words, the projecting parts 4 in the separation regions D1 and D2 guide the N₂ gas from the separation gas nozzles 41 and 42 to the first region 48A and the second region 48B.

Further, referring to FIG. 2 and FIG. 3, a reaction gas nozzle 31 is introduced in a radial direction of the turntable 2 through the circumferential wall part of the chamber body 12 in the first region 48A, and a reaction gas nozzle 32 is introduced in a radial direction of the turntable 2 through the circumferential wall part of the chamber body 12 in the second region 48B. Like the separation gas nozzles 41 and 42, these reaction gas nozzles 31 and 32 are supported by having respective gas introduction ports 31a and 32a, which are their base end parts, attached to the peripheral wall surface of the chamber body 12. The reaction gas nozzles 31 and 32 may be introduced to form predetermined angles relative to the radial directions.

Further, the reaction gas nozzles 31 and 32 have multiple ejection holes 33 for ejecting reaction gases toward the upper surface (a surface where there are the wafer placement parts 24) of the turntable 2. (See FIGS. 4A and 4B.) In this embodiment, the ejection holes 33 have an aperture of approximately 0.5 mm, and are arranged at intervals of approximately 10 mm along the lengthwise directions of the reaction gas nozzles 31 and 32.

Although not graphically illustrated, the reaction gas nozzle 31 is connected to a gas supply source of a first reaction gas, and the reaction gas nozzle 32 is connected to a gas supply source of a second reaction gas. Various gases including the below-described combination of gases may be used as the first reaction gas and the second reaction gas. In this embodiment, bis (tertiary-butylamino) silane (BTBAS) gas is used as the first reaction gas, and ozone (O₃) gas is used as the second reaction gas. Further, in the following description, the region below the reaction gas nozzle 31 may be referred to as a first process region P1 for causing BTBAS gas to be adsorbed on the wafers W, and the region below the reaction gas nozzle 32 may be referred to as a second process region P2 for causing O₃ gas to react with (oxidize) the BTBAS gas adsorbed on the wafers W.

Referring again to FIGS. 4A and 4B, the low, flat ceiling surface 44 is in the separation region D1 (as well as in the separation region D2 although not graphically illustrated), and the ceiling surface 45, which is higher than the ceiling surface 44, is in the first region 48A and the second region 48B. Therefore, the volumes of the first region 48A and the second region 48B are larger than the volumes of the separation spaces H in the separation regions D1 and D2. The ceiling surface 44 increases in width along the rotation direction of the turntable 2 toward the outer edge of the vacuum chamber 1. Further, as described below, the vacuum chamber 1 according to this embodiment includes evacuation ports 61 and 62 for evacuating the first region 48A and the second region 48B, respectively. These allow the first region 48A and the second region 48B to be kept lower in pressure than the separation spaces H of the separation regions Dl and D2. In this case, the BTBAS gas ejected from the reaction gas nozzle 31 in the first region 48A is prevented from reaching the second region 48B through the separation spaces H because of the high pressures of the separation spaces H of the separation regions D1 and D2. Further, the O₃ gas ejected from the reaction gas nozzle 32 in the second region 48B is prevented from reaching the first region 48A through the separation spaces H because of the high pressures of the separation spaces H of the separation regions D1 and D2. Accordingly, both reaction gases are separated by the separation regions D1 and D2, and are hardly mixed in the gas phase inside the vacuum chamber 1.

The height h1 of the lower ceiling surfaces 44 measured from the upper surface of the turntable 2 (FIG. 4A) is determined so as to allow the pressures of the separation spaces H of the separation regions D1 and D2 to be higher than the pressures of the first region 48A and the second region 48B, although depending on the amounts of N₂ gas supplied from the separation gas nozzles 41 and 42. The height h1 is preferably 0.5 mm to 10 mm, for example, and more preferably as small as possible. However, in order to prevent the turntable 2 from colliding with the ceiling surfaces 44 because of its rotation deflection, the height h1 may be approximately 3.5 mm to 6.5 mm. Likewise, the height h2 (FIG. 4A) from the lower ends of the separation gas nozzles 41 and 42 housed in the corresponding groove parts 43 of the projecting parts 4 to the upper surface of the turntable 2 may be 0.5 mm to 4 mm.

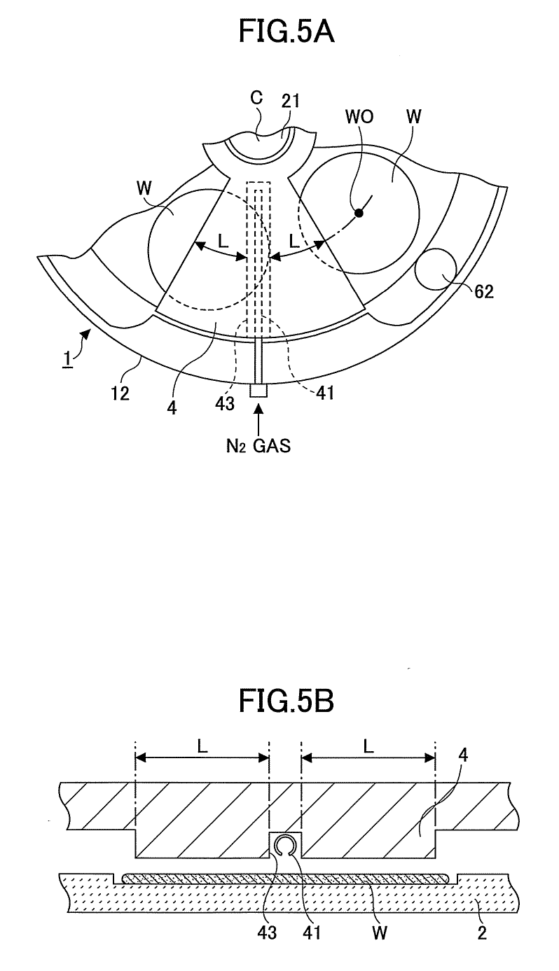

Further, as illustrated in FIGS. 5A and 5B, in each of the projecting parts 4, for example, the length L of an arc corresponding to the path of a wafer center WO is preferably approximately 1/10 to approximately 1/1, more preferably more than or equal to approximately ⅙, of the diameter of the wafer W. This makes it possible to ensure that the separation spaces H of the separation regions D1 and D2 are kept high in pressure.

According to the separation regions D1 and D2 having the above-described configuration, it is possible to further ensure separation of BTBAS gas and O₃ gas even if the turntable 2 rotates at, for example, a rotation speed of approximately 240 rpm.

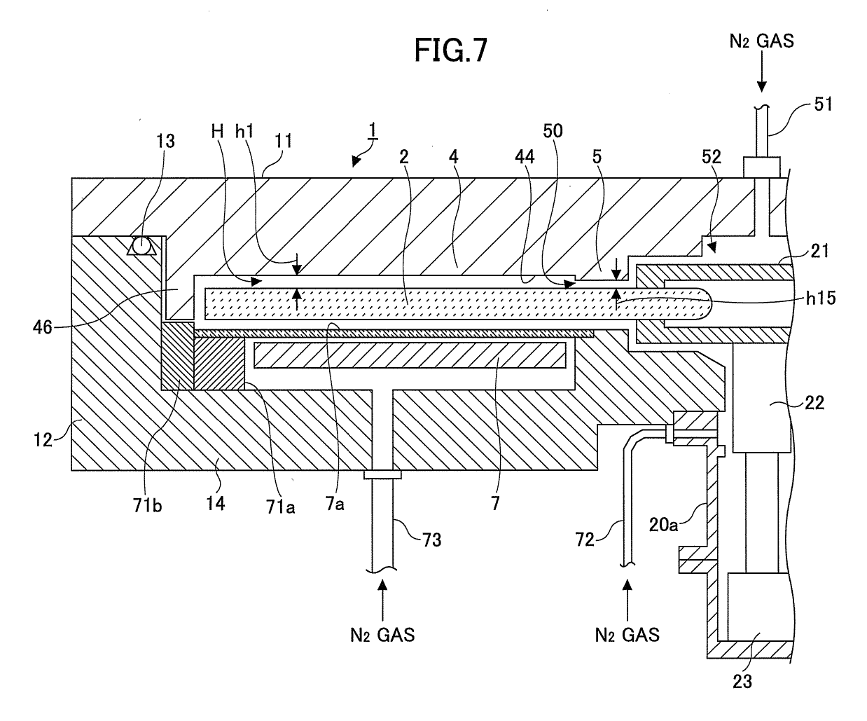

Referring again to FIG. 1, FIG. 2, and FIG. 3, an annular projecting part 5 is attached to the lower surface (ceiling surface) 45 of the ceiling plate 11 so as to surround the core part 21. The projecting part 5 faces the turntable 2 in a region outside the core part 21. In this embodiment, as clearly illustrated in FIG. 7, the height h15 of a space (gap) 50 from the turntable 2 to the lower surface of the projecting part 5 is slightly less than the height h1 of the separation space H. This is because the rotation deflection of the turntable 2 is limited near its center part. Specifically, the height h15 may be approximately 1.0 mm to approximately 2.0 mm. In other embodiments, the height h15 may be equal to the height h1, and the projecting part 5 and the projecting parts 4 may be either formed as a unit or formed as a combination of separate bodies. FIG. 2 and FIG. 3 illustrate the inside of the vacuum chamber 1 from which the ceiling plate 11 is removed with the projecting parts 4 left inside the vacuum chamber 1.

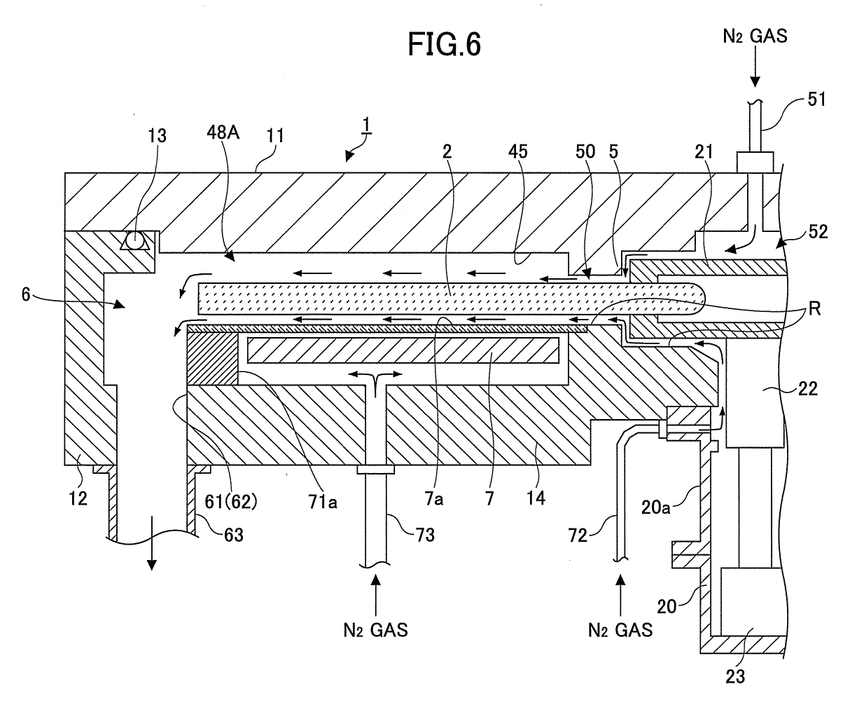

Referring to FIG. 6, which is an enlarged view of approximately half of FIG. 1, a separation gas supply pipe 51 is connected to the center part of the ceiling plate 11 of the vacuum chamber 1 so as to supply N₂ gas into a space 52 between the ceiling plate 11 and the core part 21. The N₂ gas supplied into this space 52 allows the narrow gap 50 between the projecting part 5 and the turntable 2 to be kept higher in pressure than the first region 48A and the second region 48B. This prevents the BTBAS gas ejected from the reaction gas nozzle 31 in the first region 48A from reaching the second region 48B through the high-pressure gap 50. Further, this prevents the O₃ gas ejected from the reaction gas nozzle 32 in the second region 48B from reaching the first region 48A through the high-pressure gap 50. Accordingly, both reaction gases are separated by the gap 50 and are hardly mixed in the gas phase inside the vacuum chamber 1. That is, in the film deposition apparatus of this embodiment, in order to separate BTBAS gas and O₃ gas, a center region C is provided that is defined by the rotation center part of the turntable 2 and the vacuum chamber 1 and kept higher in pressure than the first region 48A and the second region 48B.

FIG. 7 illustrates approximately half of the cross-sectional view taken along line B-B of FIG. 3, where the projecting part 4 and the projecting part 5 formed as a unit with the projecting part 4 are graphically illustrated. As graphically illustrated, the projecting part 4 has a bent portion 46 bent in an L-letter shape at its outer edge. The bent portion 46 substantially fills in a space between the turntable 2 and the chamber body 12 to prevent the BTBAS gas from the reaction gas nozzle 31 and the O₃ gas from the reaction gas nozzle 32 from mixing through this gap. The gap between the bent portion 46 and the chamber body 12 and the gap between the bent portion 46 and the turntable 2 may be substantially equal to, for example, the height h1 from the turntable 2 to the ceiling surface 44 of the projecting part 4. Further, the presence of the bent portion 46 makes it difficult for the N₂ gas from the separation gas nozzles 41 and 42 (FIG. 3) to flow toward outside the turntable 2. This furthers the N₂ gas flowing from the separation regions D1 and D2 to the first region 48A and the second region 48B. It is more preferable to provide a block member 71b below the bent portion 46 because this makes it possible to further control the separation gas flowing to a space below the turntable 2.

In view of the thermal expansion of the turntable 2, the gap between the bent portion 46 and the turntable 2 is preferably determined so that the gap becomes the above-described interval (approximately h1) when the turntable 2 is heated with a heater unit described below.

On the other hand, in the first region 48A and the second region 48B, the inner circumferential wall surface is depressed outward to form evacuation areas 6 as illustrated in FIG. 3. At the bottoms of these evacuation areas 6, for example, the evacuation ports 61 and 62 are provided as illustrated in FIG. 3 and FIG. 6. These evacuation ports 61 and 62 are connected to a vacuum evacuation unit such as a common vacuum pump 64 through respective evacuation pipes 63 as illustrated in FIG. 1. As a result, the first region 48A and the second region 48B are mainly evacuated, so that it is possible to cause the first region 48A and the second region 48B to be lower in pressure than the separation spaces H of the separation regions D1 and D2 as described above.

Further, referring to FIG. 3, the evacuation port 61 corresponding to the first region 48A is positioned below the reaction gas nozzle 31 outside the turntable 2 (in the evacuation area 6). This allows the BTBAS gas ejected from the ejection holes 33 (FIGS. 4A and 4B) of the reaction gas nozzle 31 to flow toward the evacuation port 61 in a lengthwise direction of the reaction gas nozzle 31 along the upper surface of the turntable 2. A description is given below of advantages of such an arrangement.

Referring again to FIG. 1, the evacuation pipes 63 are provided with a pressure controller 65, which controls the pressure inside the vacuum chamber 1. Alternatively, the evacuation ports 61 and 62 may be provided with corresponding pressure controllers 65. Further, the evacuation ports 61 and 62 may also be provided in the circumferential wall part of the chamber body 12 of the vacuum chamber 1 in place of the bottoms of the evacuation areas 6 (the bottom part 14 of the chamber body 12). Alternatively, the evacuation ports 61 and 62 may also be provided in the ceiling plate 11 in the evacuation areas 6. In the case of providing the evacuation ports 61 and 62 in the ceiling plate 11, however, particles in the vacuum chamber 1 may be thrown upward to contaminate the wafers W because the gas inside the vacuum chamber 1 flows upward. Therefore, it is preferable to provide the evacuation ports 61 and 62 at the bottom as graphically illustrated or in the circumferential wall part of the chamber body 12. Further, providing the evacuation ports 61 and 62 at the bottom allows the evacuation pipes 63, the pressure controller 65, and the vacuum pump 64 to be installed below the vacuum chamber 1, and is therefore advantageous in reducing the footprint of the film deposition apparatus.

As illustrated in FIG. 1 and FIGS. 6 through 8, an annular heater unit 7 serving as a heating part is provided in a space between the turntable 2 and the bottom part 14 of the chamber body 12, so that the wafers W on the turntable 2 are heated to a predetermined temperature via the turntable 2. Further, a block member 71a is provided below the turntable 2 near its periphery so as to surround the heater unit 7. Therefore, the space where the heater unit 7 is placed is separated from a region outside the heater unit 7. In order to prevent gas from flowing inside the block member 71a, the block member 71a is placed so as to maintain a slight gap between the upper surface of the block member 71a and the lower (bottom) surface of the turntable 2. Multiple purge gas supply pipes 73 are connected at predetermined angular intervals to the region where the heater unit 7 is housed through the bottom part 14 of the chamber body 12 in order to purge this region. Above the heater unit 7, a protection plate 7a that protects the heater unit 7 is supported by the block member 71a and a raised portion R described below. This makes it possible to protect the heater unit 7 even if BTBAS gas or O₃ gas flows into the space where the heater unit 7 is provided. Preferably, the protection plate 7a is made of, for example, quartz.

Referring to FIG. 6, the bottom part 14 has the raised portion R inside the annular heater unit 7. The upper surface of the raised portion R is close to the turntable 2 and the core part 21 so as to have a slight gap left between the upper surface of the raised portion R and the lower surface of the turntable 2 and between the upper surface of the raised portion R and the bottom surface of the core part 21. Further, the bottom part 14 has a center hole through which the rotation shaft 22 passes. The inside diameter of this center hole is slightly larger than the diameter of the rotation shaft 22 to leave a gap communicating with the case body 20 through the flange part 20a. A purge gas supply pipe 72 is connected to the upper portion of the flange part 20a.

According to this configuration, as illustrated in FIG. 6, N₂ gas flows from the purge gas supply pipe 72 to the space below the turntable 2 through the gap between the rotation shaft 22 and the center hole of the bottom part 14, the gap between the core part 21 and the raised portion R of the bottom part 14, and the gap between the raised portion R of the bottom part 14 and the lower surface of the turntable 2. Further, N₂ gas flows from the purge gas supply pipes 73 to the space below the heater unit 7. These N₂ gases flow into the evacuation port 61 through the gap between the block member 71a and the lower surface of the turntable 2. The N₂ gases thus flowing serve as separation gases that prevent the reaction gas of BTBAS gas (O₃ gas) from circulating through the space below the turntable 2 to mix with O₃ gas (BTBAS gas).

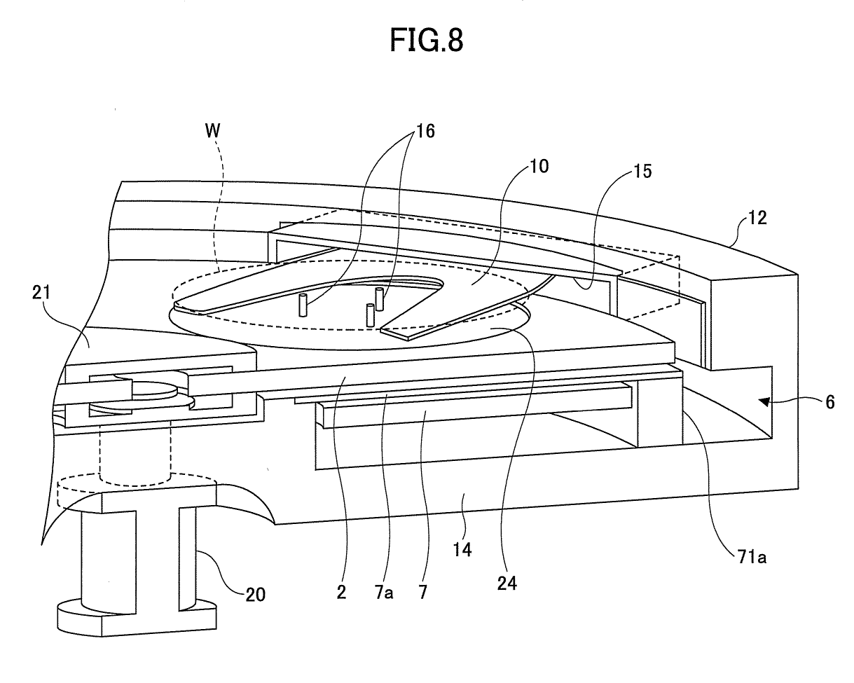

Referring to FIG. 2, FIG. 3, and FIG. 8, a transfer opening 15 is formed in the circumferential wall part of the chamber body 12. The wafers W are transferred into or out of the vacuum chamber 1 by a transfer arm 10 through the transfer opening 15. The transfer opening 15 is provided with a gate valve (not graphically illustrated), which causes the transfer opening 15 to be opened or closed. Further, three through holes (not graphically illustrated) are formed at the bottom of each placement part 24, through which three elevation pins 16 (FIG. 8) are vertically movable. The elevation pins 16 support the bottom surface of the wafer W to move up or down the wafer W, and transfer the wafer W to or receive the wafer W from the transfer arm 10.

The film deposition apparatus according to this embodiment includes a control part 100 for controlling the operation of the entire apparatus as illustrated in FIG. 3. For example, this control part 100 includes a process controller 100a formed of a computer, a user interface part 100b, and a memory unit 100c. The user interface part 100b includes a display configured to display the operating state of the film deposition apparatus and a keyboard or a touchscreen panel for allowing an operator of the film deposition apparatus to select a process recipe or allowing a process manager to change parameters of process recipes (not graphically illustrated).

The memory unit 100c contains control programs for causing the process controller 100a to execute various processes, process recipes, and parameters in various processes. Further, some of these programs include a group of steps for causing, for example, a below-described cleaning method to be executed. These control programs and process recipes are read and executed by the process controller 100a in accordance with instructions from the user interface part 100b. Further, these programs may be contained in computer-readable storage media 100d and installed in the memory unit 100c through input/output devices (not graphically illustrated) supporting these storage media 100d. Examples of the computer-readable recording media 100d include a hard disk, a CD, a CD-R/RW, a DVD-R/RW, a flexible disk, and a semiconductor memory. Further, the programs may be downloaded into the memory unit 100c via a communication line.

Next, a description is given of an operation (a film deposition method) of the film deposition apparatus of this embodiment. First, the turntable 2 rotates so that a placement part 24 is aligned with the transfer opening 15, and the gate valve (not graphically illustrated) is opened. Next, a wafer W is transferred into the vacuum chamber 1 through the transfer opening 15 by the transfer arm 10. The wafer W is received by the elevation pins 16, and after the transfer arm 10 is pulled out of the vacuum chamber 1, the wafer W is lowered to the placement part 24 by the elevation pins 16, which are driven by an elevation mechanism (not graphically illustrated). The above-described series of operations is repeated five times, so that the five wafers W are placed on the corresponding placement parts 24.

Next, N₂ gas is supplied from the separation gas nozzles 41 and 42 and N₂ gas is supplied from the purge gas supply pipes 72 and 73, while N₂ gas is also supplied from the separation gas supply pipe 51 so as to be ejected from the center region C, that is, from between the projecting part 5 and the turntable 2, along the upper surface of the turntable 2. Then, the pressure inside the vacuum chamber 1 is maintained at a preset value by the vacuum pump 64 and the pressure controller 65 (FIG. 1). At the same time or subsequently, the turntable 2 starts rotating clockwise as viewed from above. The turntable 2 is preheated to a predetermined temperature (for example, 300 ° C.) by the heater unit 7, so that the wafers W placed on this turntable 2 are heated. After the wafers W are heated and maintained at the predetermined temperature, O₃ gas is supplied to the second process region P2 through the reaction gas nozzle 32, and BTBAS gas is supplied to the first process region P1 through the reaction gas nozzle 31.

When the wafers W pass through the first process region P1 below the reaction gas nozzle 31, BTBAS molecules are adsorbed on the surfaces of the wafers W. When the wafers W pass through the second process region P2 below the reaction gas nozzle 32, O₃ molecules are adsorbed on the surfaces of the wafers W, so that the BTBAS molecules are oxidized by the O₃. Accordingly, when the turntable 2 rotates so that the wafers W pass through both the process region P1 and the process region P2 one time each, a single molecular layer (or two or more molecular layers) of silicon oxide is formed on the surfaces of the wafers W. Next, the wafers W pass through the regions P1 and P2 alternately multiple times, so that a silicon oxide film having a predetermined thickness is deposited on the surfaces of the wafers W. After the deposition of the silicon oxide film having a predetermined thickness, supplying BTBAS gas and O₃ gas is stopped, supplying N₂ gas from the separation gas nozzles 41 and 42, the separation gas supply pipe 51, and the purge gas supply pipes 72 and 73 is stopped, and the rotation of the turntable 2 is stopped. Then, the wafers W are successively transferred out of the vacuum chamber 1 by the transfer arm 10 in the operation opposite to the operation of transferring them in, so that the film deposition process ends.

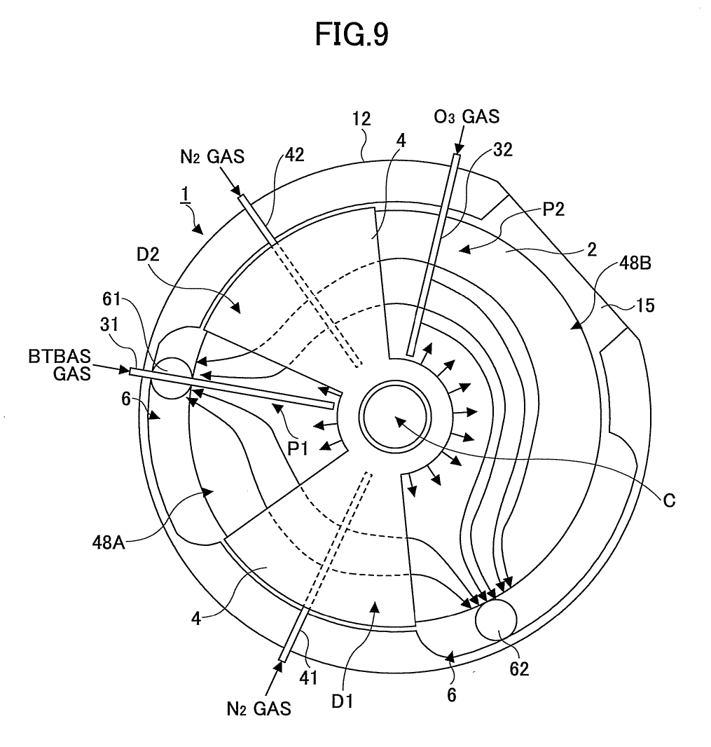

Next, a description is given, with reference to FIG. 9, of a gas flow pattern inside the vacuum chamber 1. The N₂ gas ejected from the separation gas nozzle 41 of the separation region D1 flows out from the separation space H between the projecting part 4 and the turntable 2 (see FIG. 4A) to the first region 48A and the second region 48B so as to cross the radial direction of the turntable 2 at substantially right angles. The N₂ gas that has flowed out from the separation region D1 to the first region 48A is suctioned by the evacuation port 61 so as to flow into the evacuation port 61 along with N₂ gas from the center region C. Therefore, near the reaction gas nozzle 31, the N₂ gas flows substantially along a lengthwise direction of the reaction gas nozzle 31. Accordingly, the N₂ gas that has flowed out from the separation region D1 to the first region 48A hardly crosses the first process region P1 below the reaction gas nozzle 31. Therefore, the BTBAS gas ejected from the reaction gas nozzle 31 toward the turntable 2 is prevented from being diluted with the N₂ gas, and is adsorbable on the wafers W at a high concentration.

Further, the N₂ gas ejected from the separation gas nozzle 42 of the separation region D2 and flowing out from the separation space H of the separation region D2 to the first region 48A also is suctioned by the evacuation port 61, and flows along a lengthwise direction of the reaction gas nozzle 31 into the evacuation port 61. Therefore, the N₂ gas from the separation region D2 also hardly crosses the first process region P1 below the reaction gas nozzle 31. Accordingly, prevention of the dilution of the BTBAS gas with the N₂ gas is further ensured.

On the other hand, the N₂ gas that has flowed out from the separation region D2 to the second region 48B, while being caused to flow outward by the N₂ gas from the center region C, flows toward and into the evacuation port 62. Further, the O₃ gas ejected from the reaction gas nozzle 32 of the second region 48B also flows in the same manner into the evacuation port 62.

In this case, the N₂ gas may pass through the process region P2 below the reaction gas nozzle 32 of the second region 48B, so that the O₃ gas ejected from the reaction gas nozzle 32 may be diluted. In this embodiment, however, the second region 48B is larger than the first region 48A, and the reaction gas nozzle 32 is disposed as much apart from the evacuation port 62 as possible, so that the O₃ gas may sufficiently react with (oxidize) the BTBAS molecules adsorbed on the wafers W before flowing into the evacuation port 62 after being ejected from the reaction gas nozzle 32. That is, according to this embodiment, the effect of the dilution of the O₃ gas with the N₂ gas is limited.

Part of the O₃ gas ejected from the reaction gas nozzle 32 may flow toward the separation region D2. As described above, however, the separation space H of the separation region D2 is higher in pressure than the second region 48B. Therefore, the O₃ gas is prevented from entering the separation region D2, and flows along with the N₂ gas from the separation region D2 to reach the evacuation port 62. Further, part of the O₃ gas flowing from the reaction gas nozzle 32 to the evacuation port 62 may flow toward the separation region D1, but is prevented from entering the separation region D1 the same as described above. That is, the O₃ gas is prevented from reaching the first region 48A through the separation region D1 or D2, so that both reaction gases are prevented from mixing.

Further, in this embodiment, as long as the N₂ gas flowing from the separation regions D1 and D2 in directions substantially perpendicular to the radial direction of the turntable 2 toward the first region 48A may be prevented from crossing the first process region P1 below the first reaction gas nozzle 31 by changing the flowing direction of the N₂ gas to a direction along a lengthwise direction of the reaction gas nozzle 31, the evacuation port 61 may not be disposed immediately below the reaction gas nozzle 31, and may be disposed with an offset from the reaction gas nozzle 31. In this case, the evacuation port 61 may be offset to either the upstream side or the downstream side in the rotation direction of the turntable 2. Considering the rotation direction of the turntable 2, however, a large amount of N₂ gas flows out from the separation region D1 to the first region 48A, so that the upstream side is more preferable in order to prevent this N₂ gas from crossing the first process region P1. Further, the evacuation port 61 may also be disposed between a region below the reaction gas nozzle 31 and the separation region D1.

Further, the evacuation ports 61 and 62 (as well as an evacuation port 63 described below), which have a circular opening in the graphically illustrated case, may alternatively have an elliptical or rectangular opening. Further, the evacuation port 61 (or 63) may have an opening that extends from below the reaction gas nozzle 31 (or 32) toward the upstream side in the rotation direction of the turntable 2 along the curvature of the inner circumferential wall surface of the chamber body 12. Furthermore, in the evacuation area 6, one evacuation port may be provided below the reaction gas nozzle 31 (or 32), and one or more other evacuation ports may be provided on the upstream side of the one evacuation port in the rotation direction of the turntable 2.

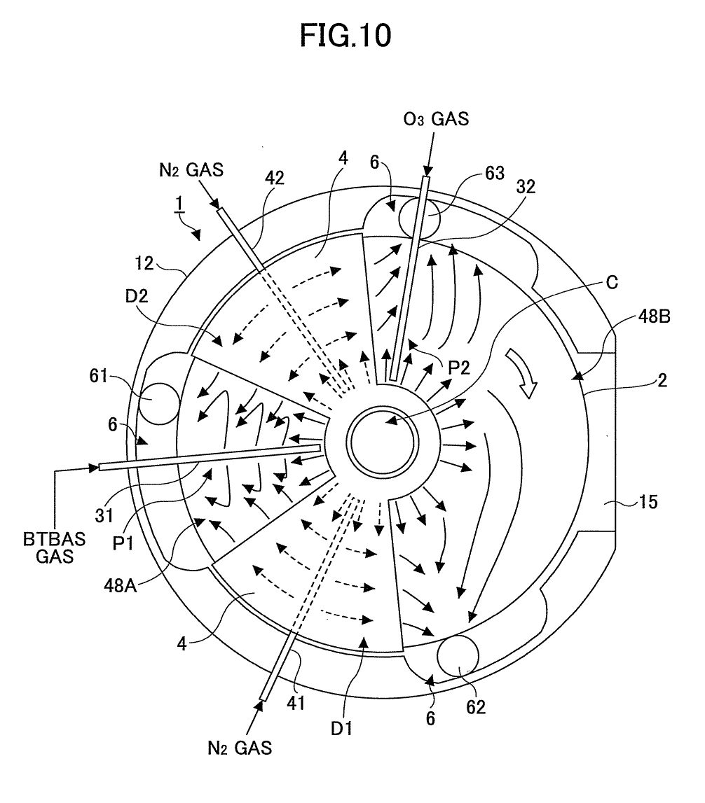

As illustrated in FIG. 10, the evacuation port 63 may be provided below the reaction gas nozzle 32 outside the turntable 2. According to this, the O₃ gas ejected from the reaction gas nozzle 32 is prevented from being diluted with the N₂ gas, so that the O₃ gas also may reach the wafers W at a high concentration. The arrangement of FIG. 9 or the arrangement of FIG. 10 may be selected suitably depending on the O₃ gas. Further, an evacuation port may also be provided below each of the reaction gas nozzle 31 and the reaction gas nozzle 32.

In the case of introducing the reaction gas nozzles 31 and 32 from the center side of the vacuum chamber 1 instead of through the circumferential wall part of the chamber body 12, the reaction gas nozzles 31 and 32 may be terminated above the peripheral edge of the turntable 2. In this case, evacuation ports may be provided on the lengthwise extensions of such reaction gas nozzles. This also causes the above-described effects to be produced.

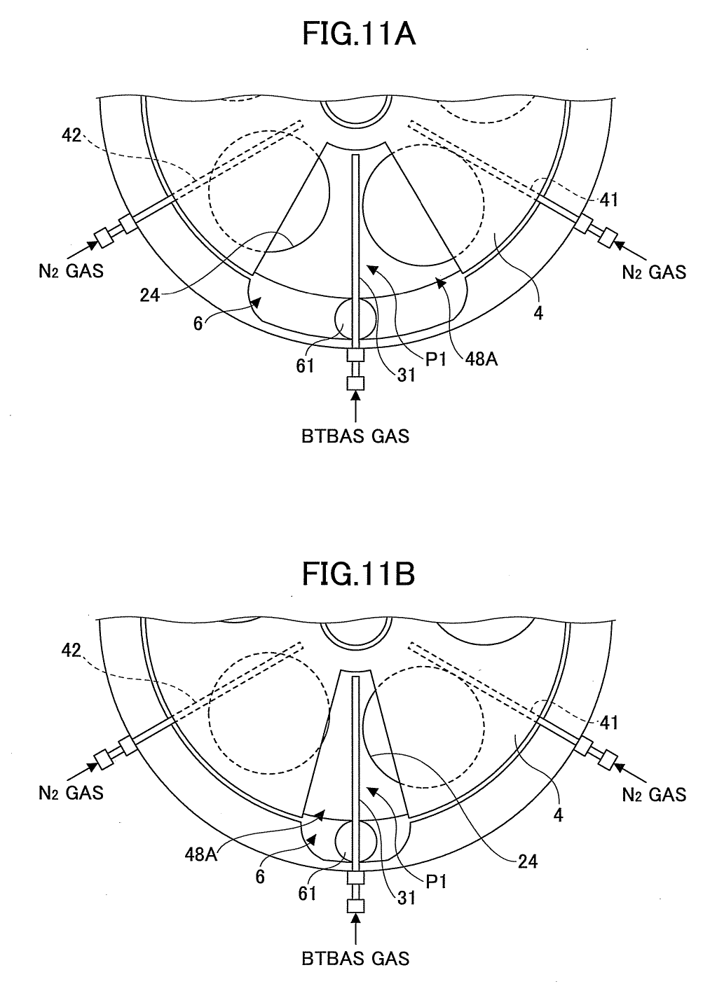

Further, as illustrated in FIG. 11A, the reaction gas nozzle 31 may be disposed at the center of the first region 48A, and the evacuation port 61 may be disposed below the reaction gas nozzle 31 outside the turntable 2 (in the evacuation area 6). Further, the width of the first region 48A may be determined as desired, and may be smaller than in other drawings as illustrated in FIG. 11B. This facilitates defining the first region 48A and the second region 48B as well as other regions corresponding to other reaction gases in the vacuum chamber 1, thus making it possible to deposit a film of a multinary compound by ALD.

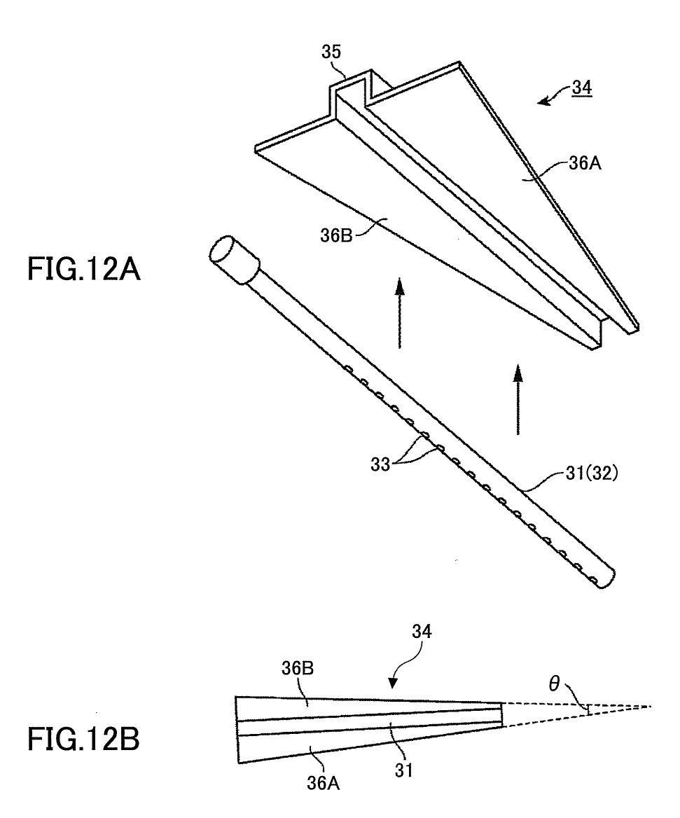

Next, a description is given, with reference to FIGS. 12A and 12B, of a configuration for supplying the wafers W (the turntable 2) with reaction gases at higher concentrations. FIGS. 12A and 12B illustrate a nozzle cover 34 to be attached to each of the reaction gas nozzles 31 and 32. The nozzle cover 34 includes a base part 35 extending along the lengthwise directions of the reaction gas nozzle 31 (32) and having a cross section of an angular C-letter shape. The base part 35 is disposed to cover the reaction gas nozzle 31 (32). A flow regulatory plate 36A and a flow regulatory plate 36B are attached to one and the other, respectively, of two opening ends of the base part 35 extending in the above-described lengthwise directions.

As clearly illustrated in FIG. 12B, in this embodiment, the flow regulatory plates 36A and 36B are formed symmetrically with respect to the center axis of the reaction gas nozzle 31 (32). Further, the length of each of the flow regulatory plates 36A and 36B along the rotation direction of the turntable 2 increases toward the peripheral part of the turntable 2. Therefore, the nozzle cover 34 has a substantially sectorial planar shape. Here, the opening angle θ of the sector indicated by dotted lines in FIG. 12B, which is determined in consideration of the size of the projecting part 4 of the separation region D1 (D2) as well, is preferably, for example, more than or equal to 5° and less than 90°, and more preferably, for example, more than or equal to 8° and less than 10°.

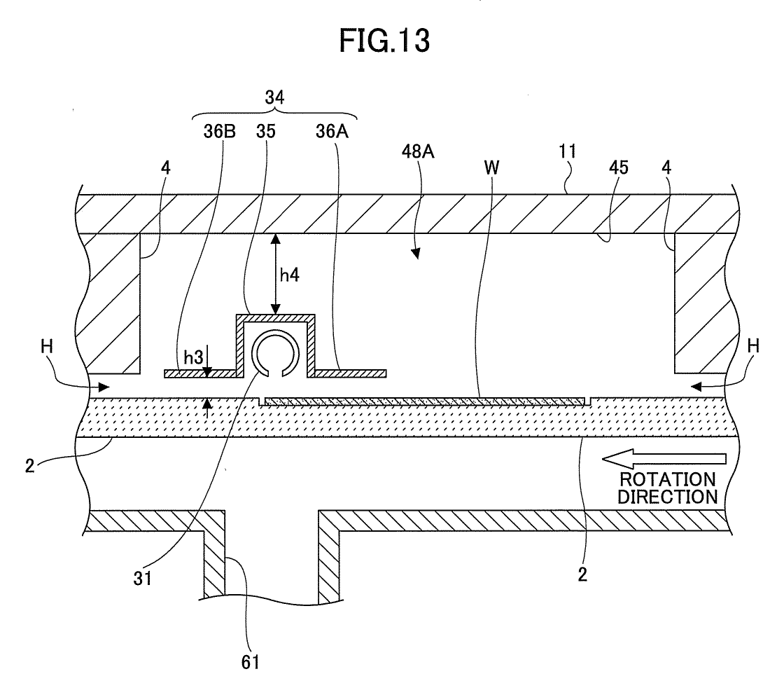

FIG. 13 is an inside view of the vacuum chamber 1 taken from outside the reaction gas nozzle 31 in its lengthwise directions. As graphically illustrated, the nozzle cover 34 configured as described above is attached to the reaction gas nozzle 31 (32) so that the flow regulatory plates 36A and 36B are in proximity and substantially parallel to the upper surface of the turntable 2. Here, for example, relative to the height of 15 mm to 150 mm of the higher ceiling surface 45 from the upper surface of the turntable 2, the height h3 of the flow regulating plate 36A from the upper surface of the turntable 2 may be, for example, 0.5 mm to 4 mm, and the interval h4 between the base part 35 of the nozzle cover 34 and the higher ceiling surface 45 may be, for example, 10 mm to 100 mm. Further, the flow regulatory plate 36A and the flow regulatory plate 36B are disposed on the upstream side and the downstream side, respectively, of the reaction gas nozzle 31 (32) in the rotation direction of the turntable 2. According to this configuration, the N₂ gas flowing out from the separation space H between the projecting part 4 and the turntable 2 on the upstream side in the rotation direction to the first region 48A is more likely to flow to a space above the reaction gas nozzle 31 and is less likely to enter the process region P1 below the reaction gas nozzle 31 because of the flow regulatory plate 36A. As a result, the dilution of the BTBAS gas from the reaction gas nozzle 31 with the N₂ gas is further controlled.

Because of the centrifugal effect due to the rotation of the turntable 2, the N₂ gas may be high in flow velocity near the peripheral edge of the turntable 2. Therefore, the effect of preventing the N₂ gas from entering the first process region P1 may be reduced near the peripheral edge. As illustrated in FIG. 12B, however, the flow regulatory plate 36A increases in width toward the peripheral part of the turntable 2, so that it is possible to cancel reduction in the N₂ gas entry preventing effect.

Further, while the nozzle cover 34 attached to the reaction gas nozzle 31 is illustrated in FIG. 13, the nozzle cover 34 may alternatively be attached to the reaction gas nozzle 32 or to each of the reaction gas nozzles 31 and 32. Further, in the case where no evacuation port is provided below the reaction gas nozzle 32 as illustrated in FIG. 9, the nozzle cover 34 may be attached only to this reaction gas nozzle 32.

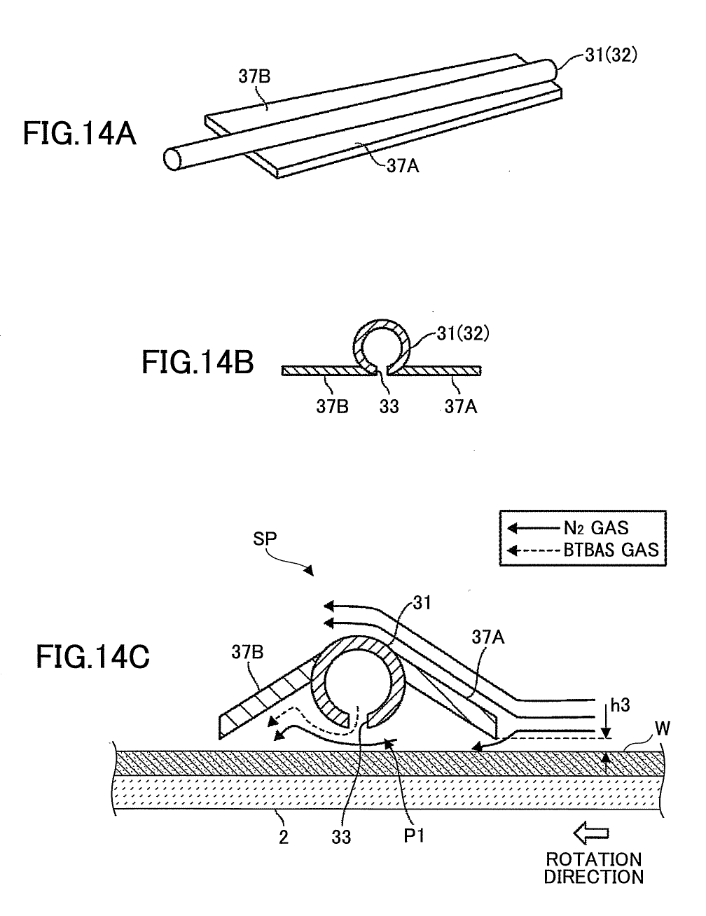

A description is given below, with reference to FIGS. 14A through 14C, of variations of the nozzle cover 34. As illustrated in FIGS. 14A and 14B, flow regulatory plates 37A and 37B may be attached directly to the reaction gas nozzle 31 (32) without using the base part 35 (FIG. 12A). In this case as well, it is possible to dispose the flow regulatory plates 37A and 37B at positions of the height h3 from the upper surface of the turntable 2, so that the same effect may be produced as with the above-described nozzle cover 34. In this example as well, like the flow regulator plates 36A and 36B illustrated in FIGS. 12A and 12B, the flow regulatory plates 37A and 37B preferably form a substantially sectorial shape as viewed from above.

Further, the flow regulatory plates 36A, 36B, 37A, and 37B may not necessarily be parallel to the turntable 2. For example, as long as the height h3 from the turntable 2 (wafers W) is maintained so that it is possible to make it easier for the N₂ gas to flow into a space SP above the reaction gas nozzle 31 (32), the flow regulatory plates 37A and 37B may be inclined toward the turntable 2 from the upper part of the reaction gas nozzle 31 as illustrated in FIG. 14C. The graphically-illustrated flow regulatory plate 37A is also preferable in being able to guide the N₂ gas to the space SP.

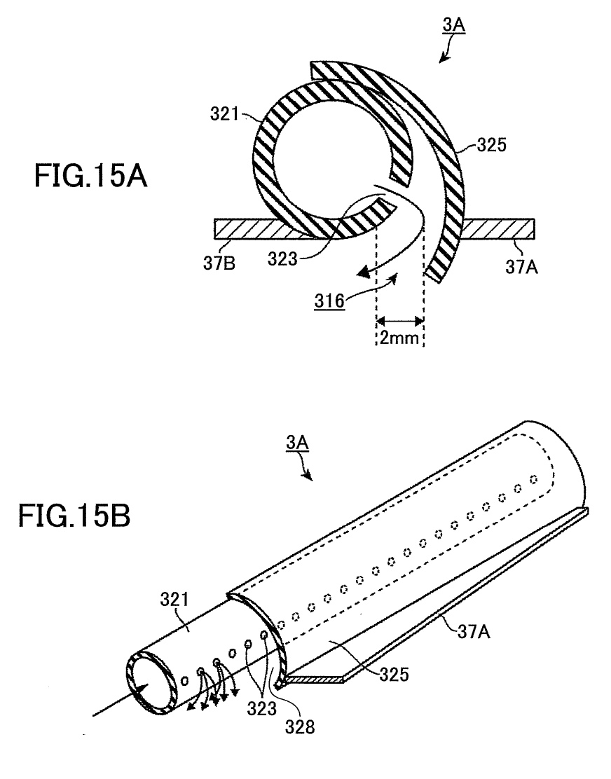

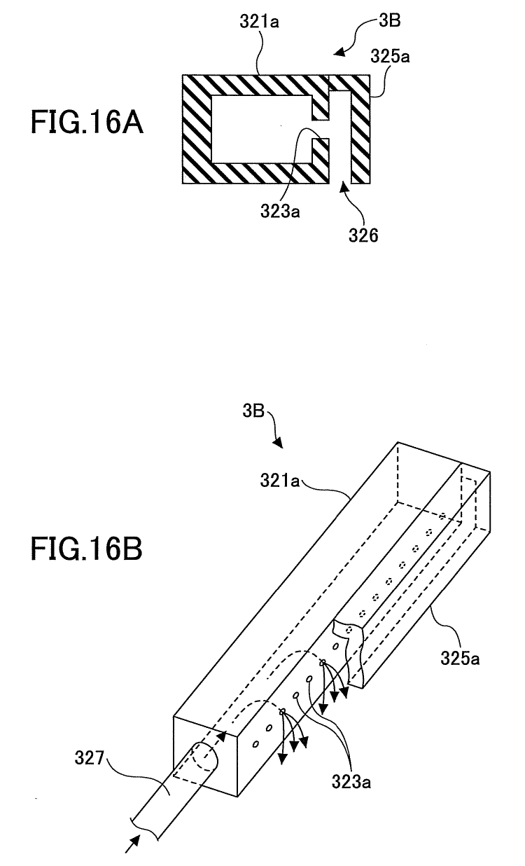

Next, a description is given, with reference to FIGS. 15A and 15B and FIGS. 16A and 16B, of other nozzle cover variations. These variations may be referred to as reaction gas nozzles integrated with a nozzle cover or reaction gas nozzles having the function of a nozzle cover. Therefore, in the following description, these variations are referred to as reaction gas injectors.

Referring to FIGS. 15A and 15B, a reaction gas injector 3A includes a reaction gas nozzle 321 having a cylindrical shape the same as the reaction gas nozzles 31 and 32. The reaction gas nozzle 321 may be provided to penetrate through the circumferential wall part of the chamber body 12 (FIG. 1) of the vacuum chamber 1. Like the reaction gas nozzles 31 and 32, the reaction gas nozzle 321 has multiple ejection holes 323 that are approximately 0.5 mm in inside diameter and arranged in the lengthwise directions of the reaction gas nozzle 321 at intervals of, for example, 10 mm. However, the reaction gas nozzle 323 is different from the reaction gas nozzles 31 and 32 in that the ejection holes 323 are open at a predetermined angle to the upper surface of the turntable 2. Further, a guide plate 325 is attached at the upper end of the reaction gas nozzle 321. The guide plate 325 has a curvature greater than the curvature of the cylinder of the reaction gas nozzle 321. A gas passage 316 is formed between the reaction gas nozzle 321 and the guide plate 325 because of their difference in curvature. A reaction gas supplied from a gas source not graphically illustrated to the reaction gas nozzle 321 is ejected from the ejection holes 323 to reach the wafer W (FIG. 13) placed on the turntable 2 through the gas passage 316.

Further, the flow regulatory plate 37A extending toward the upstream side in the rotation direction of the turntable 2 is attached to the lower end part of the guide plate 325. The flow regulatory plate 37B extending toward the downstream side in the rotation direction of the turntable 2 is attached to the lower end of the reaction gas nozzle 321.

In the reaction gas injector 3A thus configured, the N₂ gas from the separation regions D1 and D2 is less likely to enter a process region below the reaction gas nozzle 321 because the flow regulatory plates 37A and 37B are close to the upper surface of the turntable 2. Accordingly, the prevention of the dilution of the reaction gas from the reaction gas nozzle 321 with the N₂ gas is further ensured.

The reaction gas is jetted against the guide plate 325 in the process of reaching the gas passage 316 from the reaction gas nozzle 321 through the ejection holes 323. Therefore, the reaction gas spreads in the lengthwise directions of the reaction gas nozzle 321 as indicated by multiple arrows in FIG. 15B. Therefore, the gas concentration is made uniform in the gas passage 316. That is, this variation is preferable in being able to make uniform the thickness of a film deposited on the wafer W.

Referring to FIG. 16A, a reaction gas injector 3B includes a reaction gas nozzle 321a formed of a quadrangular pipe. As illustrated in FIG. 16B, the reaction gas nozzle 321a has multiple reaction gas outflow holes 323a in one sidewall. The reaction gas outflow holes 323a are, for example, 0.5 mm in inside diameter and are arranged at intervals of, for example, 5 mm along the lengthwise directions of the reaction gas nozzle 321a. Further, a guide plate 325a having an inverse L-letter shape is attached to the sidewall, in which the reaction gas outflow holes 323 are formed, with a predetermined interval (for example, 0.3 mm) between the guide plate 325a and the sidewall.

Further, as illustrated in FIG. 16B, a gas introduction pipe 327 introduced through the circumferential wall part (see, for example, FIG. 2) of the chamber body 12 of the vacuum chamber 1 is connected to the reaction gas nozzle 321a. As a result, the reaction gas nozzle 321a is supported, and, for example, BTBAS gas is supplied to the reaction gas nozzle 321a through the gas introduction pipe 327 to be supplied from the reaction gas outflow holes 323a to the turntable 2 through a gas passage 326. Further, the reaction gas nozzle 321a of this example is disposed so that the gas passage 326 is positioned on the upstream side in the rotation direction of the turntable 2.

According to the reaction gas injector 3B thus configured, the lower surface of the reaction gas nozzle 321a may be placed at the position of the height h3 from the upper surface of the turntable 2, so that the N₂ gas from the separation regions D1 and D2 is more likely to flow to a space above the reaction gas injector 3B and is less likely to enter a process region below the reaction gas injector 3B. Further, since the lower surface of the reaction gas nozzle 321a is disposed on the downstream side of the gas passage 326 in the rotation direction of the turntable 2, it is possible to cause the BTBAS gas supplied from the gas passage 326 to reside for a relatively long time between the turntable 2 and the reaction gas nozzle 321a. Therefore, it is possible to improve the efficiency of the adsorption of the BTBAS gas on the wafers W. Further, since the reaction gas that has flowed out from the reaction gas outflow holes 323a collides with the guide plate 325a to spread as indicated by arrows in FIG. 16B, the concentration of the reaction gas is made uniform along the lengthwise directions of the gas passage 326.

The reaction gas nozzle 321a may be disposed so that the gas passage 326 is positioned on the downstream side in the rotation direction of the turntable 2. In this case, the lower surface of the reaction gas nozzle 321a is placed on the upstream side of the gas passage 326 in the rotation direction of the turntable 2 so as to be able to contribute to preventing the N₂ gas from entering a space below the reaction gas nozzle 321a. Therefore, the prevention of the dilution of the reaction gas with the N₂ gas is further ensured.

The reaction gas injectors 3A and 3B illustrated in FIGS. 15A and 15B and FIGS. 16A and 16B, respectively, may be used, for example, to supply O₃ gas onto the surface of the turntable 2.

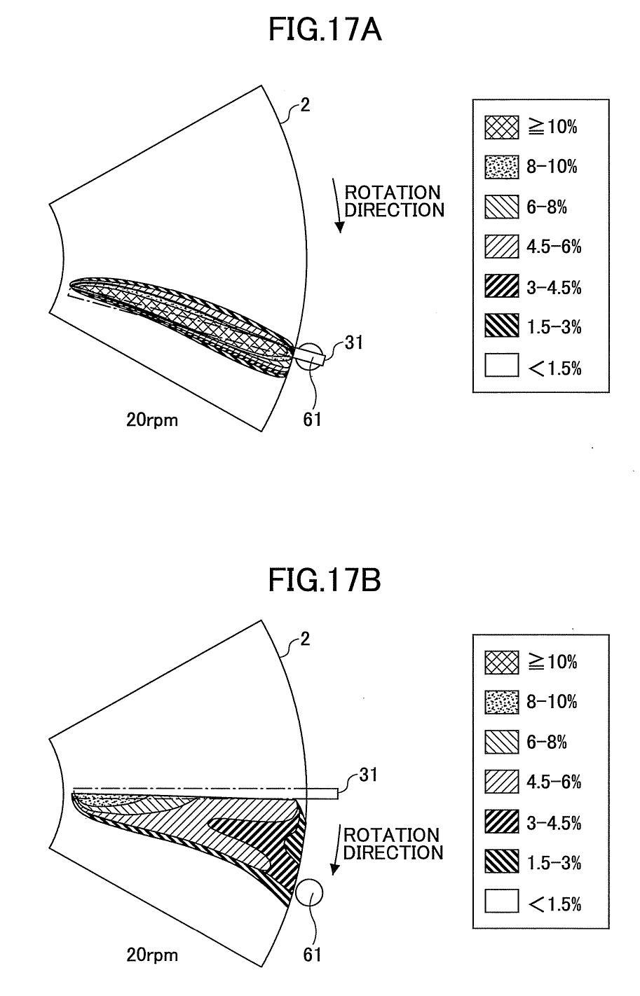

Next, a description is given, with reference to FIGS. 17A and 17B through FIG. 19, of the results of a simulation conducted with respect to the concentration of a reaction gas near the upper surface of the turntable 2. FIG. 17A illustrates how BTBAS gas from the reaction gas nozzle 31 spreads over the turntable 2 in the case of disposing the evacuation port 61 below the reaction gas nozzle 31 in the evacuation area 6 as illustrated. On the other hand, FIG. 17B illustrates how a reaction gas from the reaction gas nozzle 31 spreads over the turntable 2 in the case of disposing the evacuation port 61 at a position significantly displaced to the downstream side in the rotation direction of the turntable 2 from below the reaction gas nozzle 31. This simulation is conducted under the following conditions:

the amount of supply of BTBAS gas from the reaction gas nozzle 31: 100 sccm;

the amount of supply of N₂ gas from the separation gas nozzles 41 and 42: 14,500 sccm;

the rotation speed of the turntable 2: 20 rpm; the interval between the reaction gas nozzle 31 and the turntable 2: 4 mm;

the inside diameter of the ejection holes 33 of the reaction gas nozzle 31: 0.5 mm; and the interval (pitch) of the ejection holes 33: 10 mm .

The nozzle cover 34 (FIGS. 12A and 12B and FIGS. 14A through 14C) is not attached to the reaction gas nozzle 31.

As illustrated in FIG. 17A, in the case of disposing the evacuation port 61 below the reaction gas nozzle 31, the reaction gas concentration is more than or equal to approximately 10% in a narrow area in the entire reaction gas nozzle 31 in its lengthwise directions. Further, the reaction gas does not spread so wide on the downstream side in the rotation direction of the turntable 2 as well. Further, it is shown that the reaction gas slightly spreads to the upstream, side of the reaction gas nozzle 31 in the rotation direction of the turntable 2. On the other hand, in the case where the evacuation port 61 is significantly displaced from below the reaction gas nozzle 31, the reaction gas concentration is more than or equal to 10% in no area as illustrated in FIG. 17B, and it is shown that the reaction gas spreads to the downstream side in the rotation direction of the turntable 2. Further, the reaction gas does not spread to the upstream side in the rotation direction of the turntable 2.

These results show that in the case of FIG. 17B, the reaction gas from the reaction gas nozzle 31 is carried away particularly by the N₂ gas from the upstream side of the reaction gas nozzle 31 (the separation region D1 in FIG. 2 and so on) and spreads over a wide area to be reduced in gas concentration, while in the case of FIG. 17A, the reaction gas is not carried away by the N₂ gas so that the reaction gas may be present at high concentrations in a narrow area. That is, in the case of disposing the evacuation port 61 below the reaction gas nozzle 31, the N₂ gas, after flowing out from the separation regions D1 and D2 to the first region 48A, changes its orientation to a direction along the lengthwise directions of the reaction gas nozzle 31 to flow into the evacuation port 61. Therefore, the N₂ gas does not cross the first process region P1 below the reaction gas nozzle 31, and accordingly, does not dilute the reaction gas. Further, it is believed that the reaction gas, in such a manner as to be sandwiched in the N₂ gas flowing in the direction along the lengthwise directions of the reaction gas nozzle 31, flows in the lengthwise direction into the evacuation port 61. Such a flow keeps the reaction gas at high concentrations, so that it is ensured that the reaction gas is adsorbed on the wafers W passing through the first process region P1.

Further, in the case of FIG. 17A, the reaction gas is confined to a narrow area at high concentrations without spreading. Therefore, it is further ensured that reaction gases are prevented from mixing in a gas phase. Further, since it is possible to confine a reaction gas to a narrow area, it is possible to sufficiently separate both reaction gases without increasing the flow rate of the N₂ gas from the separation gas nozzle 41 (or 42) of the separation region D1 (or D2) to excessively increase the pressure of the separation space H. Accordingly, there is also an advantage in that it is possible to reduce the flow rate of the N₂ gas and a load on the evacuation unit to reduce running costs.

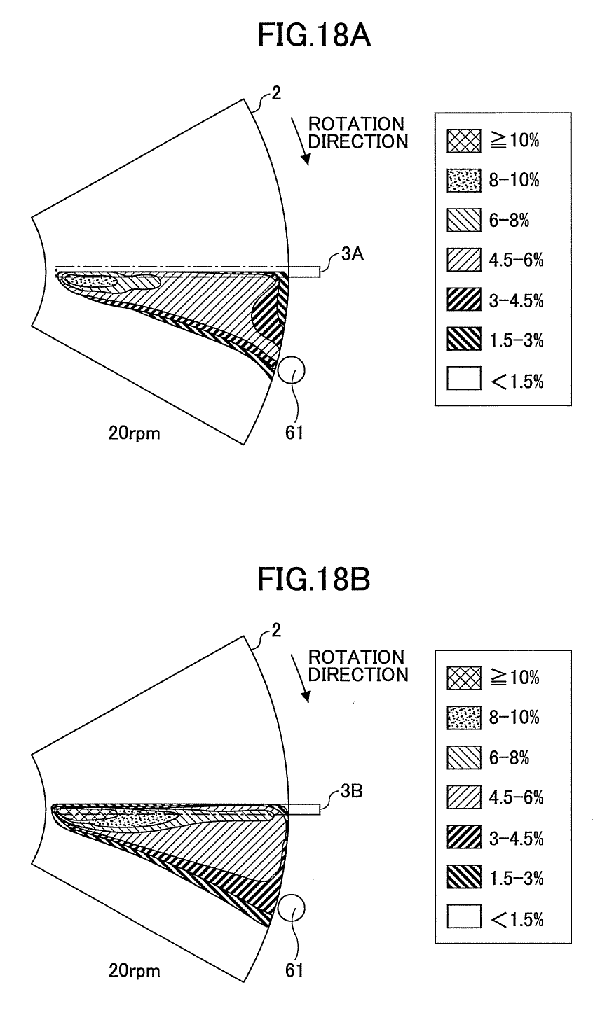

Next, a description is given of a simulation in the case of using the reaction gas injector 3A illustrated in FIGS. 15A and 15B. This simulation is conducted under the same conditions as in the case of FIG. 17B except for using the reaction gas injector 3A in place of the reaction gas nozzle 31. That is, the evacuation port 61 is significantly displaced from below the reaction gas injector 3A. FIG. 18A illustrates the results of the simulation. Although no conspicuous difference from the case of FIG. 17B is recognized, the area of a reaction gas concentration of 4.5% to 6% is wider. It may be concluded that this is because N₂ gas crossing the first process region P1 below the reaction gas injector 3A is reduced by the flow regulatory plates 37A and 37B and the guide plate 325.

Further, FIG. 18B illustrates the results of a simulation in the case of using the reaction gas injector 3B illustrated in FIGS. 16A and 16B. This simulation is conducted under the same conditions as in the case of FIG. 17B except for using the reacting gas injector 3B in place of the reaction gas nozzle 31. As graphically illustrated, the reaction gas from the reaction gas injector 3B, although spreading widely on the downstream side in the rotation direction of the turntable 2, is high in gas concentration in a wider area than in the case of FIG. 17B. The reaction gas concentration is high on the side close to the center of the vacuum chamber 1 (FIG. 1 and FIG. 2) in particular. It is believed that this is because the lower surface of the reaction gas nozzle 321a of the reaction gas injector 3B is close to the upper surface of the turntable 2 so that it is possible to reduce N₂ gas entering the first process region P1. It is concluded from the graphically-illustrated results that disposing the evacuation port 61 below the reaction gas injector 3B achieves higher gas concentrations than in the case of FIG. 17A.

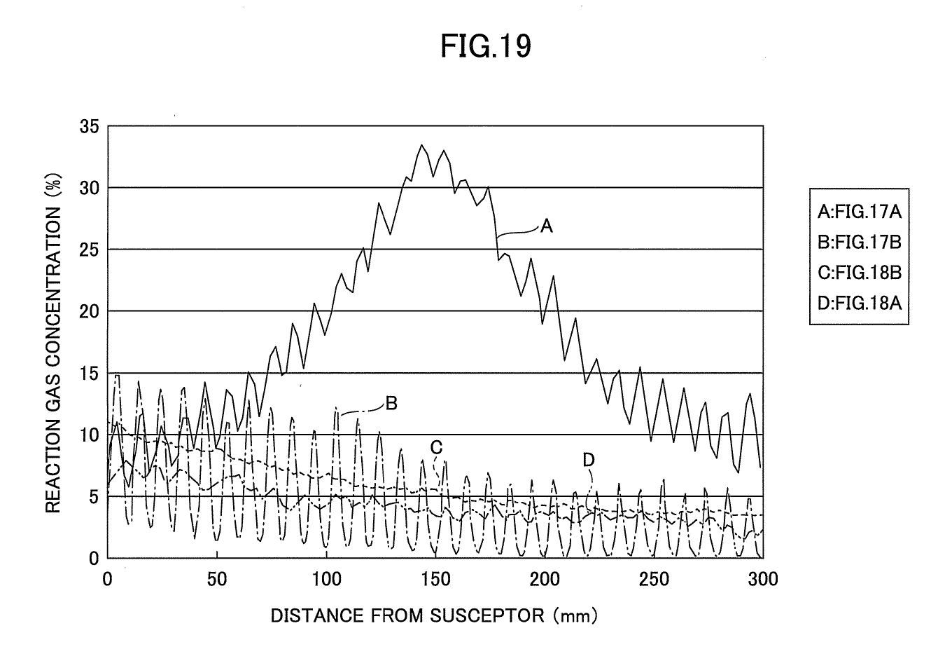

FIG. 19 illustrates concentration distributions of the reaction gas concentration along the radial direction of the turntable 2 corresponding to FIG. 17A through FIG. 18B. It is shown that in the case of disposing the evacuation port 61 below the reaction gas nozzle 31 as illustrated in FIG. 17A, the reaction gas concentration exceeds 30% near the center of the turntable 2 in its radial direction, and reaction gas concentrations substantially higher than in other cases are achieved. The cyclical increases and decreases of curved lines A and B of FIG. 19 are due to the distribution of the ejection holes 33. That is, this shows that the gas concentration is high immediately below the ejection holes 33. On the other hand, such increases and decreases are not conspicuous in curved lines C and D. This is because the reaction gas ejected from the ejection holes 323 of the reaction gas nozzle 321 in the reaction gas injector 3A and the rejection gas ejected from the reaction gas outflow holes 323a of the reaction gas nozzle 321a in the reaction gas injector 3B collide with the guide plates 325 and 325a, respectively, so that the gas concentration is made uniform in the lengthwise directions of the reaction gas injectors 3A and 3B in the gas passages 316 and 326, respectively.

Further, it may be concluded that the concentration is high near the center of the turntable 2 in its radial direction in curved line A (in the case of disposing the evacuation port 61 below the reaction gas nozzle 31) because the reaction gas flows from the end (on the side close to the center of the vacuum chamber 1) to the base end part of the reaction gas nozzle 31 so that the reaction gas concentration increases in the downstream direction of the flow while the reaction gas is discharged through the evacuation port 61 on the downstream side of the flow so that the reaction gas concentration decreases along the direction.

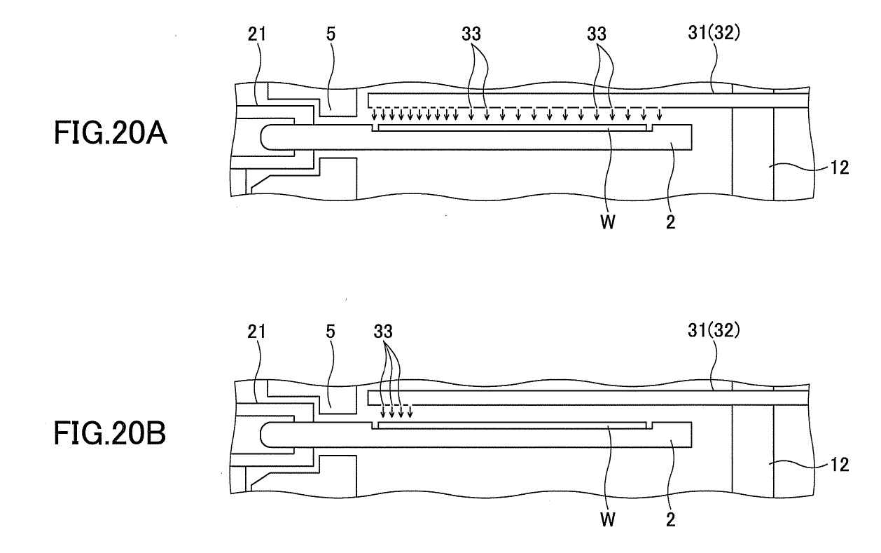

Such a reaction gas concentration distribution may be leveled by adjusting the intervals of the ejection holes 33 of the reaction gas nozzle 31 as illustrated in FIGS. 20A and 20B. Referring to FIG. 20A, the ejection holes 33 are formed at high density on the end side and at low density on the base end part side of the reaction gas nozzle 31. Further, depending on a reaction gas to be used, the ejection holes 33 may be formed only on the end side of the reaction gas nozzle 31 as illustrated in FIG. 20B. Further, ejection holes may be formed at high density on the base end part side. In the case where the reaction gas flows in a lengthwise direction of the reaction gas nozzle 31 (toward its base end part), the reaction gas concentration decreases along the direction of the reaction gas flow as the reaction gas is adsorbed on the surface of the wafer W. However, this decrease in the concentration may be canceled by forming ejection holes at high density on the base end part side.

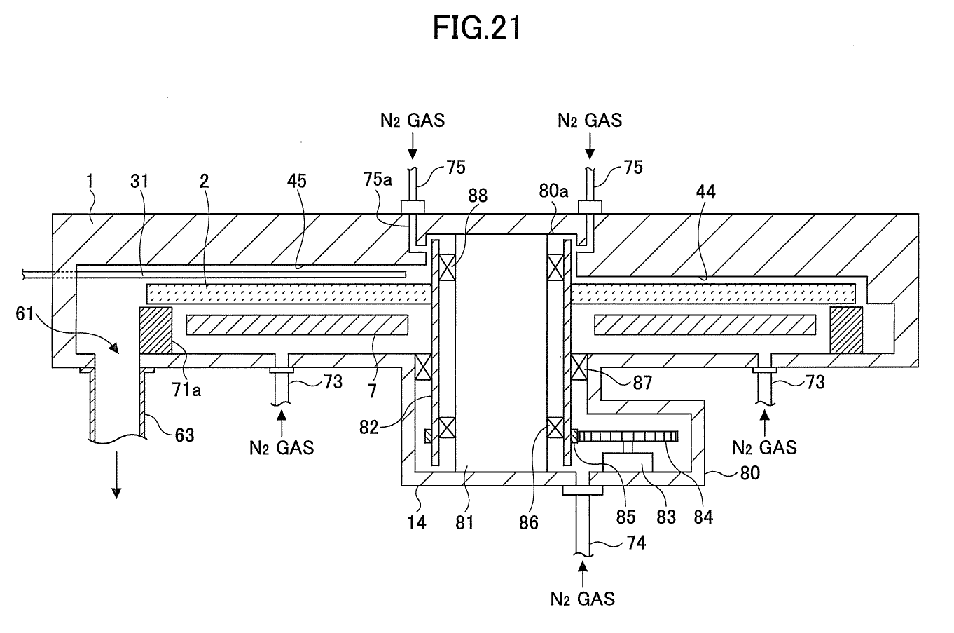

Here, a description is given of a film deposition apparatus according to another embodiment of the present invention. Referring to FIG. 21, the bottom part 14 of the chamber body 12 has a center opening, where a housing case 80 is hermetically attached. Further, the ceiling plate 11 has a center depressed part 80a. A pillar support 81 is placed on the bottom surface of the housing case 80 so that the upper end of the pillar support 81 reaches the bottom surface of the center depressed part 80a. The pillar support 81 prevents the BTBAS gas ejected from the reaction gas nozzle 31 and the O₃ gas ejected from the reaction gas nozzle 32 from mixing with each other through the center part of the vacuum chamber 1.

Further, a rotation sleeve 82 is provided to coaxially surround the pillar support 81. The rotation sleeve 82 is supported by bearings 86 and 88 attached to the exterior surface of the pillar support 81 and a bearing 87 attached to the interior side surface of the housing case 80. Further, a gear part 85 is attached to the exterior surface of the rotation sleeve 82. Further, the interior circumferential surface of the annular turntable 2 is attached to the exterior surface of the rotation sleeve 82. A drive part 83 is housed in the housing case 80, and a gear 84 is attached to a shaft extending from the drive part 83. The gear 84 engages with the gear part 85. According to this configuration, the rotation sleeve 82 and therefore the turntable 2 are caused to rotate by the drive part 83.

A purge gas supply pipe 74 is connected to the bottom of the housing case 80 to supply a purge gas to the housing case 80. This prevents reaction gases from flowing into the housing case 80. Therefore, it is possible to keep the internal space of the housing case 80 higher in pressure than the internal space of the vacuum chamber 1. Accordingly, no film deposition occurs inside the housing case 80, so that it is possible to reduce the frequency of maintenance. Further, purge gas supply pipes 75 are connected to respective conduits 75a extending from the upper exterior surface of the vacuum chamber 1 to the inner wall surface of the depressed part 80a, so that a purge gas is supplied toward the upper end part of the rotation sleeve 82. The purge gas prevents the BTBAS gas and the O₃ gas from mixing through a space between the inner wall surface of the depressed part 80a and the exterior surface of the rotation sleeve 82. FIG. 21 graphically illustrates the two purge gas supply pipes 75 and the two conduits 75a. The number of supply pipes 75 and the number of conduits 75a may be determined so as to ensure prevention of the mixture of the BTBAS gas and the O₃ gas near the space between the inner wall surface of the depressed part 80a and the exterior surface of the rotation sleeve 82.

In the film deposition apparatus according to another embodiment of the present invention as illustrated in FIG. 21, the space between the side surface of the depressed part 80a and the upper end part of the rotation sleeve 82 corresponds to an ejection hole ejecting N₂ gas as a separation gas, and this separation gas ejection hole, the rotation sleeve 82, and the pillar support 81 form a center region positioned in the center part of the vacuum chamber 1.

In the film deposition apparatus having such a configuration according to another embodiment of the present invention, the positional relationship between at least one of the reaction gas nozzles 31 and 32 and a corresponding evacuation port is the same as that in the above-described embodiment. Accordingly, the above-described effects are produced in this film deposition apparatus as well.

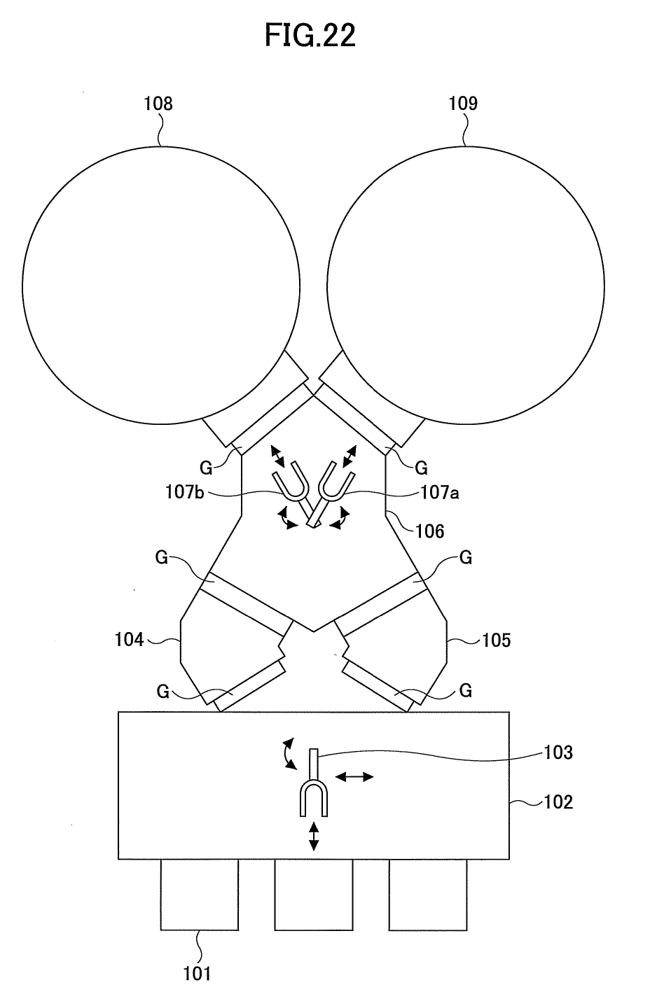

Further, film deposition apparatuses (including variations of members) according to embodiments of the present invention may be incorporated into substrate processors, a typical example of which is illustrated in FIG. 22. A substrate processor includes an atmospheric transfer chamber 102 in which a transfer arm 103 is provided, load lock chambers (preparation chambers) 104 and 105 capable of switching the atmosphere between a vacuum and an atmospheric pressure, a vacuum transfer chamber 106 in which two transfer arms 107a and 107b are provided, and film deposition apparatuses 108 and 109 according to an embodiment of the present invention. The load lock chambers 104 and 105 and the transfer chambers are coupled with openable and closable gate valves G, and the film deposition apparatuses 108 and 109 and the transfer chamber 106 are coupled with openable and closable gate valves G. Further, the load lock chambers 104 and 105 and the atmospheric transfer chamber 102 also are coupled with openable and closable gate valves G. Further, this substrate processor includes cassette stages (not graphically illustrated) on which wafer cassettes 101 such as FOUPs are placed.

The wafer cassette 101 is carried to one of the cassette stages, and is connected to a transfer port between the cassette stage and the atmospheric transfer chamber 102. Next, the lid of the wafer cassette (FOUP) 101 is opened by an opening and closing mechanism (not graphically illustrated), and a wafer is extracted from the wafer cassette 101 by the transfer arm 103. Next, the wafer is transferred to the load lock chamber 104 (105). After the load lock chamber 104 (105) is evacuated, the wafer in the load lock chamber 104 (105) is transferred to the film deposition apparatus 108 or 109 through the vacuum transfer chamber 106 by the transfer arm 107a (107b). In the film deposition apparatus 108 or 109, a film is deposited on the wafer by the above-described method. Since the substrate processor includes the two film deposition apparatuses 108 and 109 each capable of housing five wafers at a time, the substrate processor can perform molecular layer deposition at high throughput.

Film deposition apparatuses according to embodiments of the present invention may be applied not only to deposition of a silicon oxide film but also to molecular layer deposition of silicon nitride. Further, molecular layer deposition of aluminum oxide (Al₂O₃) using trymethylaluminum (TMA) and O₃ gas, molecular layer deposition of zirconium oxide (ZrO₂) using tetrakis(ethylmethylamino)zirconium (TEMAZ) and O₃ gas, molecular layer deposition of hafnium oxide (HfO₂) using tetrakis(ethylmethylamino)hafnium (TEMAH) and O₃ gas, molecular layer deposition of strontium oxide (SrO) using bis(tetra methyl heptandionate) strontium (Sr(THD)₂) and O₃ gas, molecular layer deposition of titanium oxide (TiO) using (methyl-pentadionate)(bis-tetra-methyl-heptandionate) titanium (Ti(MPD)(THD)) and O₃ gas, and the like may be performed. The O₃ gas may be replaced with oxygen plasma. The above-described effects are also produced using these combinations of gases.

All examples and conditional language recited herein are intended for pedagogical purposes to aid the reader in understanding the invention and the concepts contributed by the inventors to furthering the art, and are to be construed as being without limitation to such specifically recited examples and conditions, nor does the organization of such examples in the specification relate to a showing of the superiority or inferiority of the invention. Although the embodiments of the present inventions have been described in detail, it should be understood that various changes, substitutions, and alterations could be made hereto without departing from the spirit and scope of the invention.

What is claimed is:

1. A film deposition apparatus configured to deposit a thin film on a substrate by stacking a plurality of layers of a reaction product by carrying out a plurality of times a cycle of supplying, in turn, at least two kinds of reaction gases reacting with each other onto the substrate in a chamber, the film deposition apparatus comprising:
a turntable provided rotatably in the chamber and including a substrate placement region for placing a substrate on a surface thereof;
a first reaction gas supply part disposed in a first supply region in the chamber so as to extend in a direction to cross a rotation direction of the turntable, and configured to supply a first reaction gas onto the surface of the turntable;
a second reaction gas supply part disposed in a second supply region spaced apart from the first supply region along the rotation direction of the turntable so as to extend in a direction to cross the rotation direction of the turntable, and configured to supply a second reaction gas onto the surface of the turntable;
a separation region disposed between the first supply region and the second supply region, the separation region including
a separation gas supply part configured to eject a separation gas to separate the first reaction gas and the second reaction gas; and
a ceiling surface forming a separation space having a predetermined height between the ceiling surface and the surface of the turntable to supply the separation gas from the separation gas supply part to the first supply region and the second supply region;
a first evacuation port provided for the first supply region; and
a second evacuation port provided for the second supply region,
wherein at least one of the first evacuation port and the second evacuation port is disposed so as to guide the separation gas, supplied from the separation region to the first or second supply region corresponding to said at least one of the first evacuation port and the second evacuation port, toward and along a direction in which the first or second reaction gas supply part in the corresponding first or second supply region extends.

2. The film deposition apparatus as claimed in claim 1, wherein said at least one of the first evacuation port and the second evacuation port is disposed between a position in the direction in which the first or second reaction gas supply part extends in the corresponding first or second supply region and the separation region on an upstream side of the first or second reaction gas supply part in the rotation direction.

3. The film deposition apparatus as claimed in claim 1, further comprising:
a passage defining member attached to at least one of the first reaction gas supply part and the second reaction gas supply part, and including a plate member configured to prevent the separation gas from flowing into a space between said at least one of the first reaction gas supply part and the second reaction gas supply part and the surface of the turntable.

4. The film deposition apparatus as claimed in claim 1, wherein at least one of the first reaction gas supply part and the second reaction gas supply part comprises:
an ejection hole open in a direction offset from a direction from said at least one of the first reaction gas supply part and the second reaction gas supply part toward the surface of the turntable, the ejection hole being configured to eject the corresponding first or second reaction gas; and
a guide plate configured to guide the corresponding first or second reaction gas ejected from the ejection hole to the surface of the turntable.

5. The film deposition apparatus as claimed in claim 1, wherein the predetermined height is set so as to allow a pressure of the separation space to be kept higher than a pressure of the first supply region and a pressure of the second supply region.
